(19) United States
(12) Patent Application Publication
(10) Pub. No.: US 2006/0087025 A1
(43) Pub. Date: Apr. 27, 2006

(54) Method of manufacturing a substrate with concave portions, a substrate with concave portions, a microlens substrate, a transmission screen, and a rear projection

(75) Inventor: Nobuo Shimizu, Suwa (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 11/252,701

(22) Filed: Oct. 18, 2005

(30) Foreign Application Priority Data
Oct. 21, 2004 (JP) 2004-307461
Oct. 11, 2005 (JP) 2005-296935

(51) Int. Cl. H01L 23/48

(52) U.S. Cl. 257/696

(57) ABSTRACT

A method of manufacturing a substrate 6 provided with a plurality of concave portions 61 is disclosed. The substrate 6 is used for manufacturing a microlens substrate provided with a plurality of microlenses as convex lenses which are to be formed using the plurality of concave portions 61. The method includes the steps of: preparing a base substrate 7, the base substrate 7 having two major surfaces; forming at least one layer on the one of the two major surfaces of the base substrate 7; forming a plurality of openings 81 in the at least one layer to form a mask 8, the diameter of each of the plurality of openings 81 being in the range of 0.8 to 20 μm; forming the plurality of concave portions 61 in the base substrate 7 by subjecting the base substrate 7 with the mask 8 on which the plurality of openings 81 have been formed to an etching process so that each of the formed concave portions 61 has a substantially elliptic shape; and removing the mask 8 from the base substrate 7 (6). In this case, the plurality of formed concave portions 61 are arranged on the base substrate 7 in a houndstooth check manner. Further, in the case where the depth of each of the formed concave portions 61 in a direction perpendicular to the major surface of the base substrate 7 is defined as D (μm) and the value obtained by dividing the difference between the length of each of the formed concave portions 61 in a long axis direction and the diameter of each of the formed openings 81 by two is defined as S (μm), then D and S satisfy the relation: 0.90≦S/D≦1.40. Moreover, a ratio of an area occupied by all the plurality of formed concave portions 61 in a usable area where the plurality of concave portions 61 are formed with respect to the entire usable area is 90% or more when viewed from above the one major surface of the base substrate 7.

### CROSS-REFERENCE TO RELATED APPLICATION

This application claims priority to Japanese Patent Application No. 2004-307461 filed Oct. 21, 2004 and No. 2005-296935 filed Oct. 11, 2005, which are hereby expressly incorporated by reference herein in their entirety.

### FIELD OF THE INVENTION

The present invention relates to a method of manufacturing a substrate with concave portions, a substrate with concave portions, a microlens substrate, a transmission screen, and a rear projection.

### BACKGROUND OF THE INVENTION

In recent years, demand for a rear projection is becoming increasingly strong as a suitable display for a monitor for a home theater, a large screen television, or the like. In a transmission screen used for the rear projector, lenticular lenses are in general use. However, a conventional rear projection provided with such lenticular lenses has a problem that the vertical angle of view thereof is small although the lateral angle of view thereof is large (this is, there is a bias in the angles of view).

In order to solve such a problem, a transmission screen that uses a microlens array sheet (microlens substrate) in place of a lenticular lens is proposed (for example, see JP-A-2000-321675). However, in such a transmission screen, since the transmission screen is provided with the microlens array sheet in which a plurality of microlenses are arranged in a square lattice manner, there has been a problem that light passing through each of the microlenses interferes with each other, and it is easy to generate moire compared with the case of using a lenticular lens, in particular. Further, there has been problems that because the microlenses are arranged in the square lattice manner or the like, the light use efficiency of the transmission screen provided with the microlenses becomes low, the contrast thereof is made to become low, and a phenomenon in which the brightness of the transmission screen becomes drastically dark at a predetermined horizontal angle in the angle of view characteristics thereof (so-called, a certain-drawing phenomenon) is generated.

### SUMMARY OF THE INVENTION

It is one object of the invention to provide a transmission screen and a rear projection which can prevent moire due to interference of light from being generated and have excellent angle of view characteristics.

It is another object of the invention to provide a microlens substrate which can be appropriately applied to the manufacture of the transmission screen and rear projection described above and a substrate provided with a plurality of concave portions used to manufacture the microlens substrate.

Further, it is yet another object of the invention to provide a method of manufacturing the substrate provided with a plurality of concave portions described above efficiently.

In order to achieve the above objects, in one aspect of the invention, the invention is directed to a method of manufacturing a substrate provided with a plurality of concave portions. The substrate is used for manufacturing a microlens substrate provided with a plurality of microlenses as convex lenses which are to be formed using the plurality of concave portions. The method includes the steps of:

preparing a base substrate, the base substrate having two major surfaces;

forming at least one layer on the one of the two major surfaces of the base substrate;

forming a plurality of openings in the at least one layer to form a mask, the diameter of each of the plurality of openings being in the range of 0.8 to 20 μm;

forming the plurality of concave portions in the base substrate by subjecting the base substrate with the mask on which the plurality of openings have been formed to an etching process so that each of the formed concave portions has a substantially elliptic shape; and

removing the mask from the base substrate,

wherein the plurality of formed concave portions are arranged on the base substrate in a houndstooth check manner,

wherein, in the case where the depth of each of the formed concave portions in a direction perpendicular to the major surface of the base substrate is defined as D (μm) and the value obtained by dividing the difference between the length of each of the formed concave portions in a long axis direction and the diameter of each of the formed openings by two is defined as S (μm), then D and S satisfy the relation: 0.90≦S/D≦1.40, and

wherein a ratio of an area occupied by all the plurality of formed concave portions in a usable area where the plurality of concave portions are formed with respect to the entire usable area is 90% or more when viewed from above the one major surface of the base substrate.

This makes it possible to provide a method of manufacturing a substrate provided with a plurality of concave portions which can be appropriately used to manufacture a transmission screen and a rear projection that can prevent moire due to interference of light from being generated and have excellent angle of view characteristics.

In the method of manufacturing a substrate provided with a plurality of concave portions according to the invention, it is preferable that in the openings forming step the plurality of openings are formed so that a first column of concave portions is shifted by a half pitch of each of the plurality of concave portions in a short axis direction thereof with respect to a second column of concave portions which is adjacent to the first column of concave portions when viewed from above the one major surface of the base substrate.

Thus, the transmission screen and the rear projection provided with the microlens substrate manufactured using the substrate provided with a plurality of concave portions that has been manufactured using the method of the invention can prevent moire due to interference of light from being generated and have excellent angle of view characteristics.

In the method of manufacturing a substrate provided with a plurality of concave portions according to the invention, it is preferable that the at least one layer forming step includes the steps of:

forming a first layer constituted from chromium as a main material on the one major surface of the base substrate; and

forming a second layer constituted from chromium oxide as a main material on the first layer.

This makes it possible to form openings each having a desired shape easily and surely and to improve the adhesion between the base substrate and the mask at the etching process. As a result, it is possible to form the plurality of concave portions each having a desired shape easily and surely.

In the method of manufacturing a substrate provided with a plurality of concave portions according to the invention, it is preferable that the openings forming step includes the step of irradiating the base substrate on which the at least one layer has been formed with laser beams.

This makes it possible to form the openings each having a desired shape easily and surely.

In the method of manufacturing a substrate provided with a plurality of concave portions according to the invention, it is preferable that in the concave portions forming step the etching process is carried out using a liquid containing ammonium hydrogen difluoride, as an etchant.

This makes it possible to proceed the etching to the base substrate effectively while preventing a harmful influence on the mask or the like from being generated sufficiently, and therefore, it is possible to form the plurality of concave portions each having a desired shape easily and surely. Further, since a solution containing 4% by weight ammonium hydrogen difluoride is not poison, it is possible to prevent its influence on human bodies during work and on the environment more surely.

In the method of manufacturing a substrate provided with a plurality of concave portions according to the invention, it is preferable that in the base substrate preparing step the base substrate constituted from a material having transparency is used.

Thus, for example, it is possible to use the obtained substrate provided with a plurality of concave portions as a component (lens substrate) of a transmission screen and/or a rear projection appropriately. Further, for example, in the case where the obtained substrate provided with a plurality of concave portions is used to manufacture a microlens substrate, it is possible to appropriately carry out processes such as formation of a black matrix without removing the substrate provided with a plurality of concave portions from the microlens substrate.

In the method of manufacturing a substrate provided with a plurality of concave portions according to the invention, it is preferable that, in the case where the length of each of the formed concave portions having a substantially elliptic shape in the short axis direction thereof is defined as L₁ (μm) and the length of each of the formed concave portions in the long axis direction thereof is defined as L₂ (μm), then L₁ and L₂ satisfy the relation: 0.10≦L₁/L₂≦0.99.

Thus, the transmission screen and the rear projection provided with the microlens substrate manufactured using the substrate provided with a plurality of concave portions that has been manufactured using the method of the invention can prevent moire due to interference of light from being generated and have excellent angle of view characteristics.

In another aspect of the invention, invention is directed to a substrate provided with a plurality of concave portions. The substrate provided with a plurality of concave portions is manufactured using the method of the invention described above.

This makes it possible to provide a substrate provided with a plurality of concave portions for manufacturing a microlens substrate which can be appropriately used to manufacture a transmission screen and a rear projection that can prevent moire due to interference of light from being generated and have excellent angle of view characteristics.

In yet another aspect of the invention, the invention is directed to a microlens substrate. The microlens substrate is manufactured using the substrate with the plurality of concave portions according to the invention describe above, wherein the microlens substrate has two major surfaces, and a plurality of microlenses are formed on the one major surface of the microlens substrate.

This makes it possible to provide a microlens substrate which can be appropriately used to manufacture a transmission screen and a rear projection that can prevent moire due to interference of light from being generated and have excellent angle of view characteristics.

In the microlens substrate of the invention, it is preferable that the plurality of microlenses are formed on the one major surface of the microlens substrate so that a first column of microlenses is shifted by a half pitch of each of the plurality of microlenses in a short axis direction thereof with respect to a second column of microlenses which is adjacent to the first column of microlenses when viewed from above the one major surface of the microlens substrate.

Thus, the transmission screen and the rear projection provided with the microlens substrate of the invention can prevent moire due to interference of light from being generated and have excellent angle of view characteristics.

In the microlens substrate of the invention, it is preferable that, in the case where the length of each of the plurality of microlenses having a substantially elliptic shape in the short axis direction thereof is defined as L₁ (μm) and the length of each of the plurality of microlenses in the long axis direction thereof is defined as L₂ (μm), then L₁ and L₂ satisfy the relation: 0.10≦L₁/L₂≦0.99

Thus, the transmission screen and the rear projection provided with the microlens substrate manufactured using the substrate provided with a plurality of concave portions of the invention can prevent moire due to interference of light from being generated and have excellent angle of view characteristics.

In the microlens substrate of the invention, it is preferable that the microlens substrate is constituted from a material having transparency.

Thus, for example, it is possible to use the obtained microlens substrate as a component of a transmission screen and/or a rear projection appropriately.

In still another aspect of the invention, the invention is directed to a transmission screen. The transmission screen of the invention includes:

a Fresnel lens formed with a plurality of concentric prisms on one major surface thereof, the one major surface of the Fresnel lens constituting an emission surface thereof; and

the microlens substrate of the invention described above, the microlens substrate being arranged on the side of the emission surface of the Fresnel lens so that the one major surface thereof faces the Fresnel lens.

This makes it possible to provide a transmission screen which can prevent moire due to interference of light from being generated and have excellent angle of view characteristics.

In yet still another aspect of the invention, the invention is directed to a rear projection. The rear projection of the invention includes the transmission screen of the invention described above.

This makes it possible to provide a rear projection which can prevent moire due to interference of light from being generated and have excellent angle of view characteristics.

### BRIEF DESCRIPTION OF THE DRAWINGS

The foregoing and other objects, features and advantages of the invention will become more readily apparent from the following detailed description of preferred embodiments of the invention which proceeds with reference to the appending drawings.

FIG. 1 is a longitudinal cross-sectional view which schematically shows a microlens substrate in a preferred embodiment according to the invention.

FIG. 2 is a plan view of the microlens substrate shown in FIG. 1.

FIG. 3 is a longitudinal cross-sectional view which schematically shows a transmission screen provided with the microlens substrate shown in FIG. 1 in a preferred embodiment according to the invention.

FIG. 4 is a longitudinal cross-sectional view which schematically shows a substrate provided with a plurality of concave portions of the invention.

FIG. 5 is a longitudinal cross-sectional view which schematically shows a method of manufacturing the substrate provided with a plurality of concave portions shown in FIG. 4.

FIG. 6 is a longitudinal cross-sectional view which schematically shows one example of a method of manufacturing a microlens substrate shown in FIG. 1.

FIG. 9 is a drawing which schematically shows the configuration of a rear projection to which the transmission screen of the invention is applied.

### DETAILED DESCRIPTION OF THE INVENTION

Preferred embodiments of a method of manufacturing a substrate with concave portions, a substrate with concave portions, a microlens substrate, a transmission screen, and a rear projection according to the invention will now be described in detail with reference to the appending drawings.

In this regard, in the invention, a “substrate” indicates a concept that includes one having a relatively large wall thickness and substantially no flexibility, sheet-shaped one, film-shaped one, and the like. Further, although application of the microlens substrate and the like of the invention is not particularly limited, in the present embodiment, a description will be given for the case where the microlens substrate is mainly used as a component (convex lens substrate) included in a transmission screen and/or a rear projection.

First, the configuration of a microlens substrate of the invention will be described.

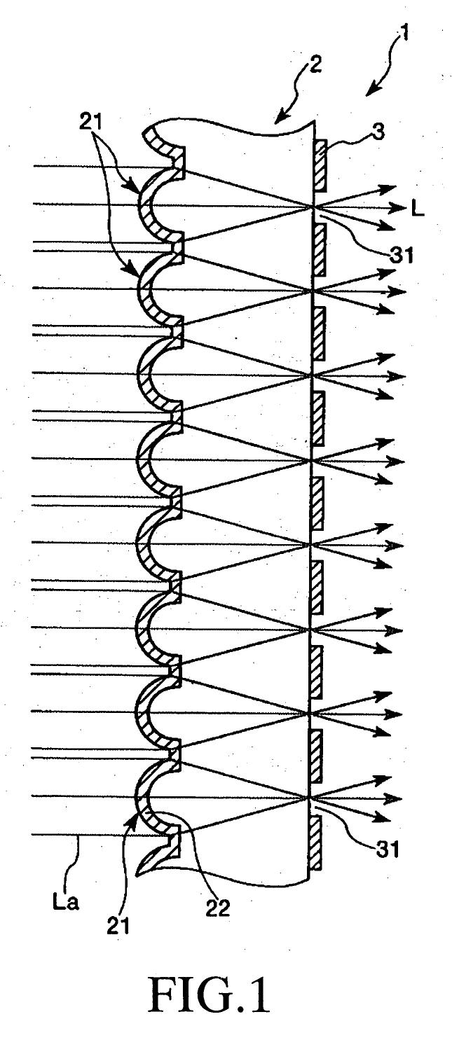

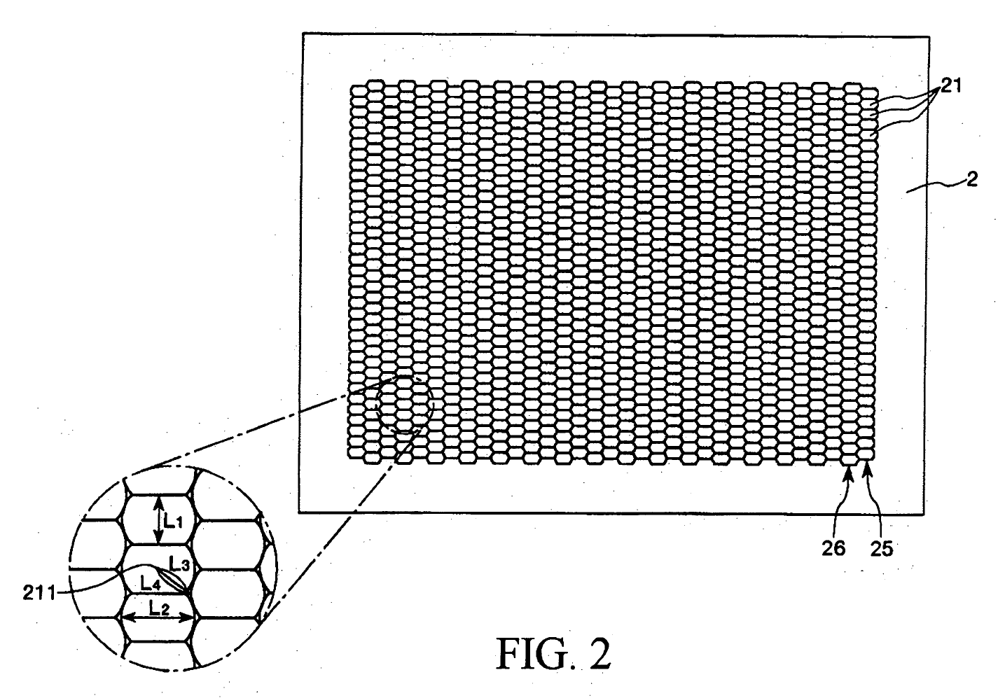

FIG. 1 is a longitudinal cross-sectional view which schematically shows a microlens substrate 1 in a preferred embodiment according to the invention. FIG. 2 is a plan view of the microlens substrate 1 shown in FIG. 1. Now, in the following explanation using FIG. 1, for convenience of explanation, a left side and a right side in FIG. 1 are referred to as a “light incident side (or light incident surface)” and a “light emission side (or light emission surface)”, respectively. In this regard, in the following description, a “light incident side” and a “light emission side” respectively indicate a “light incident side” and a “light emission side” of light for obtaining an image light, and they do not respectively indicate a “light incident side” and a “light emission side” of outside light or the like if not otherwise specified.

The microlens substrate 1 is a member that is included in a transmission screen 10 described later. As shown in FIG. 1, the microlens substrate 1 includes: a main substrate 2 provided with a plurality of microlenses 21 in a predetermined pattern at one major surface thereof (light incident surface); and a black matrix (light shielding layer) 3 formed of a material having light shielding effect at the other major surface thereof (light emission surface). Further, the microlens substrate 1 is provided with a coloring portion (outside light absorbing portion) 22 at the light incident surface thereof (that is, the light incident side of each of the microlenses 21) if needed.

The main substrate 2 is generally constituted from a material having transparent. The constituent material of the main substrate 2 is not particularly limited, but the main substrate 2 is composed of a resin material as a main material. The resin material is a transparent material having a predetermined index of refraction.

As for the concrete constituent material of the main substrate 2, for example, polyolefin such as polyethylene, polypropylene, ethylene-propylene copolymer, ethylene-vinyl acetate copolymer (EVA) and the like, cyclic polyolefin, denatured polyolefin, polyvinyl chloride, polyvinylidene chloride, polystyrene, polyamide (such as nylon 6, nylon 46, nylon 66, nylon 610, nylon 612, nylon 11, nylon 12, nylon 6-12, nylon 6-66), polyimide, polyamide-imide, polycarbonate (PC), poly-(4-methylpentene-1), ionomer, acrylic resin, acrylonitrile-butadiene-styrene copolymer (ABS resin), acrylonitrile-styrene copolymer (AS resin), butadiene-styrene copolymer, polyoxymethylene, polyvinyl alcohol (PVA), ethylene-vinyl alcohol copolymer (EVOH), polyester such as polyethylene terephthalate (PET), polybutylene terephthalate (PBT), and polycyclohexane terephthalate (PCT), polyether, polyether ketone (PEK), polyether ether ketone (PEEK), polyether imide, polyacetal (POM), polyphenylene oxide, denatured polyphenylene oxide, polysulfone, polyether sulfone, polyphenylene sulfide, polyarylate, liquid crystal polymer such as aromatic polyester, fluoro resins such as polytetrafluoroethylene (PTFE), polyfluorovinylidene and the like, various thermoplastic elastomers such as styrene based elastomer, polyolefin based elastomer, polyvinylchloride based elastomer, polyurethane based elastomer, polyester based elastomer, polyamide based elastomer, polybutadiene based elastomer, trans-polyisoprene based elastomer, fluorocarbon rubber based elastomer, chlorinated polyethylene based elastomer and the like, epoxy resins, phenolic resins, urea resins, melamine resins, unsaturated polyester, silicone based resins, urethane based resins, and the like; and copolymers, blended bodies and polymer alloys and the like having at least one of these materials as a main ingredient may be mentioned. Further, in this invention, a mixture of two or more kinds of these materials may be utilized (for example, a blended resin, a polymer alloy, a laminate body comprised of two or more layers using two or more of the materials mentioned above).

The resin material constituting the main substrate 2 normally has an absolute index of refraction more than each of those of various gases (that is, atmosphere at which the microlens substrate 1 is used). It is preferable that the concrete absolute index of refraction of the resin material is in the range of 1.2 to 1.9. More preferably it is in the range of 1.35 to 1.75, and further more preferably it is in the range of 1.45 to 1.60. In the case where the absolute index of refraction of the resin material has a predetermined value within the above range, it is possible to further improve the angle of view characteristics of a transmission screen 10 provided with the microlens substrate 1 while keeping the light use efficiency of the transmission screen 10.

The microlens substrate 1 is provided with the plurality of microlenses 21 each having a convex surface as a convex lens on the side of the light incident surface thereof from which the light is allowed to enter the microlens substrate 1. In the present embodiment, each of the microlenses 21 has a substantially elliptic shape (a flat shape or a substantial bale shape) in which a perpendicular width thereof is smaller than a lateral width when viewed from above the light incident surface of the microlens substrate 1. In the case where each of the microlenses 21 has such a shape, it is possible to particularly improve the angle of view characteristics of the transmission screen 10 provided with the microlens substrate 1 while preventing disadvantage such as moiré from being generated efficiently. In particular, in this case, it is possible to improve the angle of view characteristics in both the horizontal and vertical directions of the transmission screen 10 provided with the microlens substrate 1.

In the case where the length (or pitch) of each of the microlenses 21 in a short axis (or minor axis) direction thereof is defined as L₁ (μm) and the length (or pitch) of each of the microlenses 21 in a long axis (or major axis) direction thereof is defined as L₂ (μm) when viewed from above the light incident surface of the microlens substrate 1, it is preferable that the ratio of L₁/L₂ is in the range of 0.10 to 0.99 (that is, it is preferable that L₁ and L₂ satisfy the relation: 0.10≦L₁/L₂≦0.99). More preferably it is in the range of 0.50 to 0.95, and further more preferably it is in the range of 0.60 to 0.80. By restricting the ratio of L₁/L₂ within the above range, the effect described above can become apparent.

It is preferable that the length L₁ of each of the microlenses 21 in the minor axis direction thereof when viewed from above the light incident surface of the microlens substrate 1 is in the range of 2 to 500 μm. More preferably it is in the range of 20 to 300 μm, and further more preferably it is in the range of 30 to 100 μm. In the case where the length of each of the microlenses 21 in the minor axis direction thereof is restricted within the above range, it is possible to obtain sufficient resolution in the image projected on the transmission screen 10 and further enhance the productivity of the microlens substrate 1 (including the transmission screen 10) while preventing disadvantage such as moiré from being generated efficiently.

Further, it is preferable that the length L₂ of each of the microlenses 21 in the major axis direction thereof when viewed from above the light incident surface of the microlens substrate 1 is in the range of 5 to 750 μm. More preferably it is in the range of 25 to 500 μm, and further more preferably it is in the range of 50 to 150 μm. In the case where the length of each of the microlenses 21 in the major axis direction thereof is restricted within the above range, it is possible to obtain sufficient resolution in the image projected on the transmission screen 10 and further enhance the productivity of the microlens substrate 1 (including the transmission screen 10) while preventing disadvantage such as moiré from being generated efficiently.

Moreover, it is preferable that the radius of curvature of each of the microlenses 21 in the minor axis direction thereof (hereinafter, referred to simply as “radius of curvature of the microlens 21” is in the range of 5 to 150 μm. More preferably it is in the range of 15 to 150 μm, and further more preferably it is in the range of 25 to 50μm. By restricting the radius of curvature of the microlens 21 within the above range, it is possible to improve the angle of view characteristics of the transmission screen 10 provided with the microlens substrate 1. In particular, in this case, it is possible to improve the angle of view characteristics in both the horizontal and vertical directions of the transmission screen 10 provided with the microlens substrate 1.

Furthermore, in the case where the height of each of the microlenses 21 is defined as H (μm) and the length of the microlens 21 in a short axis (or minor axis) direction thereof is defined as L₁ (μm), then H and L₁ satisfy the relation: 0.3≦L₁/H≦5. More preferably H and L₁ satisfy the relation: 0.9≦L₁/H≦1.4, and further more preferably H and L₁ satisfy the relation: 1.2≦L₁/H≦1.4. In the case where H and L₁ satisfy such a relation, it is possible to improve the angle of view characteristics particularly while preventing moire due to interfere of light from being generated effectively.

Further, the plurality of microlenses 21 are arranged on the main substrate 2 in a houndstooth check manner. By arranging the plurality of microlenses 21 in this way, it is possible to prevent disadvantage such as moire from being generated effectively. On the other hand, for example, in the case where the microlenses 21 are arranged on the main substrate 2 in a square lattice manner or the like, it is difficult to prevent disadvantage such as moire from being generated sufficiently. Further, in the case where the microlenses 21 are arranged on the main substrate 2 in a random manner, it is difficult to improve the share of the microlenses 21 in a usable area in which the microlenses 21 are formed sufficiently, and it is difficult to improve light transmission into the microlens substrate 1 (light use efficiency) sufficiently. In addition, the obtained image becomes dark.

Although the microlenses 21 are arranged on the main substrate 2 in a houndstooth check manner when viewed from above one major surface of the microlens substrate 1 as described above, it is preferable that a first column 25 constituted from a plurality of microlenses 21 is shifted by a half pitch of each of the microlenses 21 in a short axis direction thereof with respect to a second column 26 adjacent to the first column 25. This makes it possible to improve the angle of view characteristics particularly while preventing moire due to interfere of light from being generated effectively.

As described above, by specifying the shape of the microlens 21, the arrangement pattern of the microlenses 21, share of the microlenses 21, and the like strictly, it is possible to improve the angle of view characteristics particularly while preventing the moire due to interfere of light from being generated effectively. It is possible to manufacture the microlens substrate as described above using a substrate provided with a plurality of concave portions manufactured by means of a method (will be described later).

Moreover, each of the microlenses 21 is formed as a convex lens which protrudes toward the light incident side thereof, and is designed so that the focal point f thereof is positioned in the vicinity of each of openings 31 provided on the black matrix (light shielding layer) 3. In other words, parallel light La that enters the microlens substrate 1 from a direction substantially perpendicular to the microlens substrate 1 (parallel light La from a Fresnel lens 5 described later) is condensed by each of the microlenses 21 of the microlens substrate 1, and is focused on the focal point f in the vicinity of each of openings 31 provided on the black matrix (light shielding layer) 3. In this way, since the light patting through each of the microlenses 21 focuses in the vicinity of each of the openings 31 of the black matrix 3, it is possible to enhance the light use efficiency of the microlens substrate 1 particularly. Further, since the light patting through each of the microlenses 21 focuses in the vicinity of each of the openings 31, it is possible to reduce the area of each of the openings 31.

Further, it is preferable that the ratio of an area (projected area) occupied by all the microlenses 21 in a usable area where the microlenses 21 are formed with respect to the entire usable area is 90% or more when viewed from above the light incident surface of the microlens substrate 1 (that is, a direction shown in FIG. 2). More preferably the ratio is 96% or more, further more preferably the ratio is in the range of 97 to 99.5%. In the case where the ratio of the area occupied by all the microlenses (convex lenses) 21 in the usable area with respect to the entire usable area is 90% or more, it is possible to reduce straight light passing through an area other than the area where the microlenses 21 reside, and this makes it possible to enhance the light use efficiency of the transmission screen 10 provided with the microlens substrate 1 further. In this regard, in the case where the length of one microlens 21 in a direction from the center of the one microlens 21 to the center of a non-formed area on which the four adjacent microlenses 2 including the one microlens 2 are not formed is defined as L₃ (μm) and the length between the center of the one microlens 21 and the center of the non-formed area is defined as L₄ (μm) when viewed from above the light incident surface of the microlens substrate 1, the ratio of an area (projected area) occupied by all the microlenses 21 in a usable area where the microlenses 21 are formed with respect to the entire usable area can be approximated by the ratio of the length of the line segment L₃ (μm) to the length of the line segment L₄ (μm) (that is, L₃/L_{4×100} (%)) (see FIG. 2).

Further, as described above, the colored portion 22 is provided on the light incident surface of the microlens substrate 1 (that is, on the light incident side of each of the microlenses 21). The light entering the microlens substrate 1 from the light incident surface thereof can penetrate such a colored portion 22 efficiently, and the colored portion 22 has a function of preventing outside light from being reflected to the light emission side of the microlens substrate 1. By providing such a colored portion 22, it is possible to obtain a projected image having excellent contrast.

In particular, in the invention, the colored portion 22 is one that is formed by supplying a coloring liquid (particularly, a coloring liquid having a special feature of composition) onto the main substrate 2 (will be described later). To explain this special feature in detail, the colored portion 22 is one that is formed by supplying a coloring liquid (will be described later) onto the main substrate 2 so that a coloring agent in the coloring liquid impregnates the inside of the main substrate 2 (microlenses 21). In the case where the colored portion 22 is formed in this way, it is possible to heighten adhesion of the colored portion 22 compared with the case where the colored portion 22 is laminated on the outer peripheral surface of the main substrate 2. As a result, for example, it is possible to prevent a harmful influence due to change in the index of refraction in the vicinity of the interface between the colored portion 22 and the main substrate 2 on the optical characteristics of the microlens substrate from being generated more surely.

Further, since the colored portion 22 is formed by supplying the coloring liquid onto the main substrate 2, it is possible to reduce variation in the thickness of the respective portions (in particular, the variation in the thickness that does not correspond to the surface shape of the main substrate 2). This makes it possible to prevent disadvantage such as color heterogeneity from being generated in the projected image. Moreover, although the colored portion 22 is constituted from a material containing a coloring agent, the main component thereof is generally the same as the main component of the main substrate 2 (microlens substrate 1). Therefore, a rapid change in the index of refraction or the like is hardly generated in the vicinity of the boundary between the colored portion 22 and the other non-colored portion. As a result, it is easy to design the optical characteristics of the microlens substrate 1 as a whole, and it is possible to stabilize the optical characteristics of the microlens substrate 1 and to heighten the reliability thereof.

The color density of the colored layer 22 is not particularly limited. It is preferable that the color density of the colored layer 22 indicated by Y value (D65/2° angle of view) on the basis of spectral transmittance is in the range of 20 to 85%. More preferably it is in the range of 35 to 70%. In the case where the concentration of the coloring agent in the colored portion 22 is restricted within the above ranges, it is possible to improve the contract of the image formed by the light penetrating the microlens substrate 1 particularly. On the other hand, in the case where the color density of the colored portion 22 is below the lower limit given above, the light transmission of the incident light is lowered and the obtained image cannot have sufficient brightness. As a result, there is a possibility that the contrast of the image becomes insufficient. Further, in the case where the color density of the colored portion 22 is over the upper limit given above, it is difficult to prevent the outside light (that is, outside light entering the microlens substrate 1 from the side opposite to the light incident side) from being reflected sufficiently, and since the increasing amount of front side luminance of black indication (black luminance) becomes large when a light source is fully turned off at a bright room, there is a possibility that the effect to improve the contrast of the projected image cannot be obtained sufficiently.

The color of the colored portion 22 is not particularly limited. It is preferable that the color of the colored portion 22 is an achromatic color, particularly black as appearance using a coloring agent in which the color thereof is based on blue and red, brown or yellow is mixed therein. Further, it is preferable that light having specific wavelengths for controlling balance of light's three primary colors (RGB) of a light source is selectively absorbed in the colored portion 22 or penetrates the colored portion 22. This makes it possible to prevent the outside light from being reflected. The tone of color of the image formed from the light penetrating the microlens substrate 1 can be expressed exactly, and chromatic coordinate is widened (the width of expression of the tone of color is made to widen sufficiently), and therefore a darker black can be expressed. As a result, it is possible to improve the contrast of the image, in particular.

Moreover, the black matrix 3 is provided on the light emission surface of the microlens substrate 1. In this case, the black matrix 3 is constituted from a material having a light shielding effect and formed in a laminated manner. By providing such a black matrix 3, it is possible to absorb outside light (which is not preferable to from a projected image) in the black matrix 3, and therefore it is possible to improve the image projected on a screen which has excellent contrast. In particular, by providing both the colored portion 22 as described above and the black matrix 3, it is possible to enhance the contrast of the image projected by the microlens substrate 1. Such a black matrix 3 is provided with a plurality of openings 31 on light path of the light penetrating each of the microlenses 21. Thus, the light condensed by each of the microlenses 21 can pass through the openings 31 of the black matrix 3 efficiently. As a result, it is possible to heighten the light use efficiency of the microlens substrate 1.

Further, it is preferable that the average thickness of the black matrix 3 is in the range of 0.01 to 5 μm. More preferably it is in the range of 0.01 to 3 μm, and further more preferably it is in the range of 0.03 to 1 μm. In the case where the average thickness of the black matrix 3 is restricted within the above ranges, it is possible to fulfill the function of the black matrix 3 more efficiently while preventing involuntary disadvantage such as separation and crack of the black matrix 3 more surely. For example, it is possible to improve the contrast of the image projected to a screen of a transmission screen 10 provided with the microlens substrate 1.

Next, a transmission screen 10 provided with the microlens substrate 1 as described above will now be described.

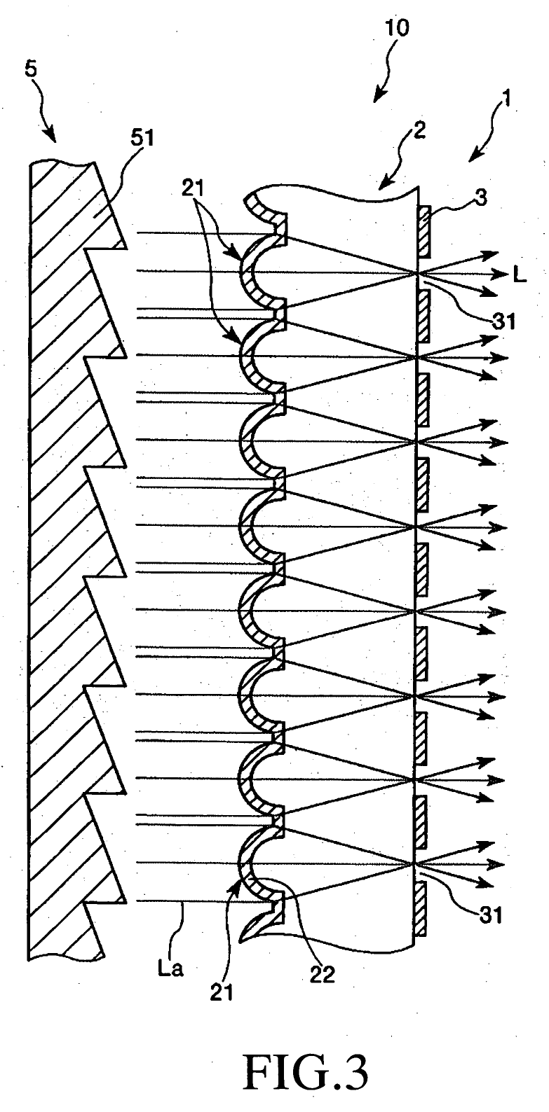

FIG. 3 is a longitudinal cross-sectional view which schematically shows a transmission screen 10 provided with the microlens substrate 1 shown in FIG. 1 in a preferred embodiment according to the invention. As shown in FIG. 3, the transmission screen 10 is provided with a Fresnel lens 5 and the microlens substrate 1 described above. The Fresnel lens 5 is arranged on the side of the light incident surface of the microlens substrate 1 (that is, on the incident side of light for an image), and the transmission screen 10 is constructed so that the light that has been transmitted by the Fresnel lens 5 enters the microlens substrate 1.

The Fresnel lens 5 is provided with a plurality of prisms that are formed on a light emission surface of the Fresnel lens 5 in a substantially concentric manner. The Fresnel lens 5 deflects the light for a projected image from a projection lens (not shown in the drawings), and outputs parallel light La that is parallel to the perpendicular direction of the major surface of the microlens substrate 1 to the side of the light incident surface of the microlens substrate 1.

In the transmission screen 10 constructed as described above, the light from the projection lens is deflected by the Fresnel lens 5 to become the parallel light La. Then, the parallel light La enters the microlens substrate 1 from the light incident surface on which the plurality of microlenses 21 are formed to be condensed by each of the microlenses 21 of the microlens substrate 1, and the condensed light then is focused and passes through the openings 31 of the black matrix (light shielding layer) 3. At this time, the light entering the microlens substrate 1 penetrates through the microlens substrate 1 with sufficient transmittance and the light penetrating the openings 31 is then diffused, whereby an observer (viewer) of the transmission screen 10 observes (watches) the as a flat image.

Next, a description will now be given for a substrate provided with a plurality of concave portions (for forming microlenses) of the invention which can be used suitably to manufacture the microlens substrate as described above and a method of manufacturing the same.

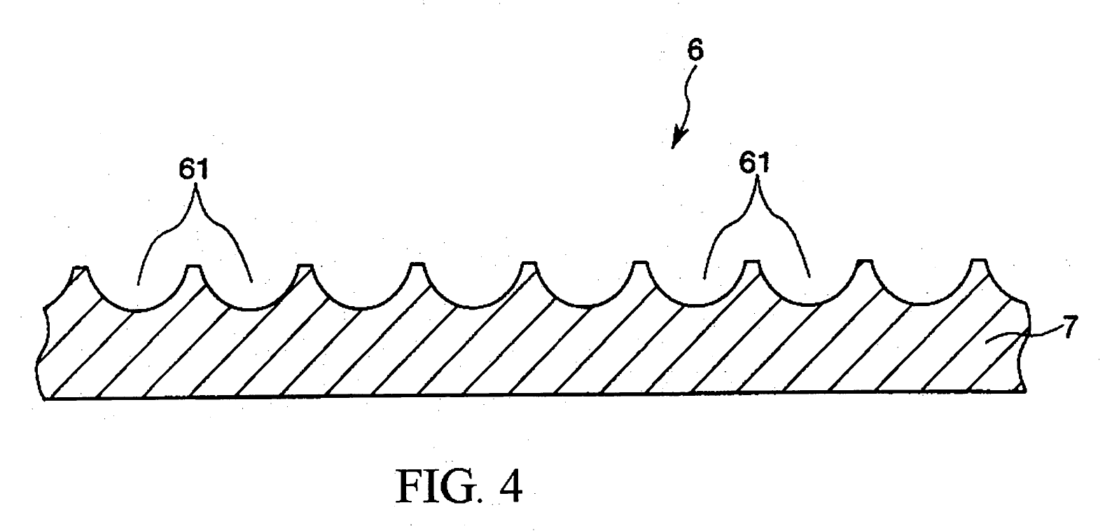

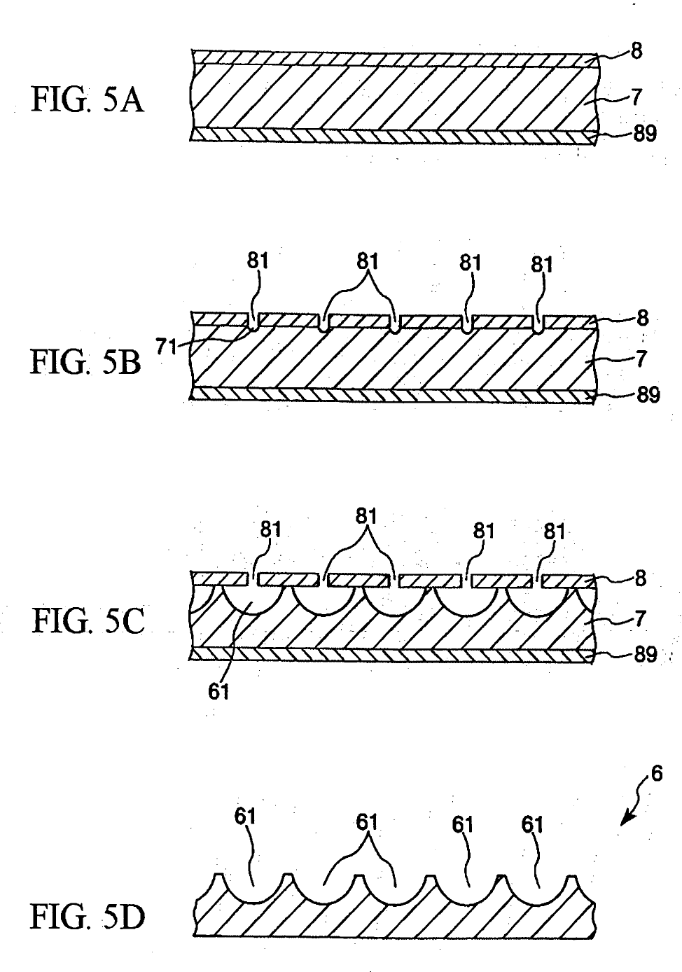

FIG. 4 is a longitudinal cross-sectional view which schematically shows a substrate 6 provided with a plurality of concave portions 61 of the invention. FIG. 5 is a longitudinal cross-sectional view which schematically shows a method of manufacturing the substrate 6 provided with a plurality of concave portions 61 shown in FIG. 4. In this regard, although a plurality of concave portions for forming microlenses 21 are actually formed on one major surface of the base substrate 7 in manufacturing the substrate 6 for manufacturing a microlens substrate 1 and a plurality of microlenses 21 (convex lenses) are actually formed on the one surface of the main substrate 2 in manufacturing the microlens substrate, in order to make the explanation understandable, a part of the substrate 6 with concave portions is shown so as to be emphasized in FIGS. 4 to 6.

The configuration of the substrate 6 provided with a plurality of concave portions 61 which can be used for manufacturing a microlens substrate 1 will first be described.

The substrate 6 with concave portions for forming microlenses 21 may be formed of any material such as various metal materials, various glass materials, and various resin materials, for example. In the case where the substrate 6 with concave portions is formed of any material having excellent stability of a shape thereof, it is possible to particularly improve the stability (reliability) of the shape of each of the concave portions 61, and it is possible to improve accuracy of dimension of each of the microlenses 21 to be formed using the substrate 6 with concave portions, in particular. Further, it is also possible to heighten the reliability of the optical characteristics of the microlens substrate 1 as a lens substrate. As for such a material having excellent stability of the shape of the concave portions 61, various metal materials, various glass materials and the like may be mentioned, for example.

Further, in the case where the substrate 6 with concave portions is formed of a material having transparency, it is possible to form a black matrix 3 on one major surface of the main substrate 2 while the substrate 6 with concave portions is in close contact with the main substrate 2 (that is, without removing the substrate 6 with concave portions from the main substrate 2) in the method of manufacturing a microlens substrate 1. This makes it possible to improve handleability of the main substrate 2 and to form the black matrix 3 thereon appropriately. In addition, in the case where the substrate 6 with concave portions is formed of a material having transparency, it is possible to use the substrate 6 with concave portions itself as a component of an optical apparatus such as a transmission screen and a rear projection or a microlens substrate (that is, a microlens substrate provided with a plurality of concave portions as concave lenses) appropriately. As for such a material having transparency, various resin materials, various glass material and the like may be mentioned, for example.

The substrate 6 with concave portions for forming microlenses 21 has a shape in which the concave portions 61 correspond to the microlenses 21 constituting the microlens substrate 1, and is provided with a plurality of concave portions 61 for forming microlenses 21 which are arranged in a manner corresponding to the arrangement pattern of the microlenses 21 of the microlens substrate 1. Each of the concave portions 61 generally has substantially the same size of each of the microlenses 21 (the same except that each of the microlenses 21 is a convex portion, while each of the concave portions 61 is a concave portion, and that one has the mirror image relation with respect to the other), and the concave portions 61 has the same arrangement pattern as the microlenses 21.

To explain it in detail, each of the concave portions 61 (concave portions 61 for forming microlenses 21) has a substantially elliptic shape (or a flat shape, a substantial bale shape) in which the perpendicular length is smaller than the lateral width (that is, the length thereof in a long axis direction is larger than the length thereof in a short axis direction) when viewed from above the one major surface of the substrate 6 with concave portions for forming microlenses 21. Since each of the concave portions 61 has such a shape, it is possible to appropriately utilize the manufacture of the microlens substrate 1 which can improve the angle of view characteristics particularly while preventing disadvantage such as moire from being generated efficiently. In addition, in the case where each of the concave portions 61 has such a substantially elliptic shape (or a flat shape, a substantial bale shape) in which the perpendicular length thereof is smaller than the lateral width thereof (that is, the length thereof in a long axis direction is larger than the length thereof in a short axis direction) when viewed from above the one major surface of the substrate 6 with concave portions for forming microlenses 21, it is possible to particularly improve the angle of view characteristics while preventing disadvantage such as moire from being generated efficiently even when the substrate 6 with concave portions itself is used for, for example, a component of an optical apparatus such as a transmission screen and a rear projection, in particular, a lens substrate (that is, a microlens substrate provided with a plurality of microlenses as concave lenses). In this case, it is possible to improve the angle of view characteristics in both the horizontal and vertical directions, in particular.

Further, in the case where the length (or pitch) of each of the concave portions 61 in a short axis (or minor axis) direction thereof is defined as L₁ (μm) and the length (or pitch) of each of the concave portions 61 in a long axis (or major axis) direction thereof is defined as L₂ (μm) when viewed from above the outer peripheral surface of the substrate 6 with concave portions, it is preferable that the ratio of L₁/L₂ is in the range of 0.10 to 0.99 (that is, L₁ and L₂ satisfy the relation: 0.10≦L₁/L₂≦0.99). More preferably it is in the range of 0.50 to 0.95, and further more preferably it is in the range of 0.60 to 0.80. By restricting the ratio of L₁/L₂ within the above range, the effect described above can become apparent.

Moreover, it is preferable that the length L₁ of each of the concave portions 61 in the minor axis direction thereof when viewed from above the outer peripheral surface of the substrate 6 with concave portions is in the range of 2 to 500 μm. More preferably it is in the range of 20 to 300 μm, and further more preferably it is in the range of 30 to 100 μm. In the case where the length of each of the concave portions 61 in the minor axis direction thereof is restricted within the above range, it is possible to obtain sufficient resolution in the image projected on the transmission screen 10 and further enhance the productivity of the microlens substrate 1 (and the substrate 6 with concave portions) while preventing disadvantage such as moire from being generated efficiently.

Furthermore, it is preferable that the length L₂ of each of the concave portions 61 in the major axis direction thereof when viewed from above the outer peripheral surface of the substrate 6 with concave portions is in the range of 5 to 750 μm. More preferably it is in the range of 25 to 500 μm, and further more preferably it is in the range of 50 to 150 μm. In the case where the length of each of the concave portions 61 in the major axis direction thereof is restricted within the above range, it is possible to obtain sufficient resolution in the image projected on the transmission screen 10 and further enhance the productivity of the microlens substrate 1 (and the substrate 6 with concave portions) while preventing disadvantage such as moiré from being generated efficiently.

Further, it is preferable that the radius of curvature of each of the concave portions 61 in the minor axis direction thereof (hereinafter, referred to simply as “radius of curvature of the concave portion 61” is in the range of 5 to 150 μm. More preferably it is in the range of 15 to 150 μm, and further more preferably it is in the range of 25 to 50 μm. By restricting the radius of curvature of the concave portions 61 within the above range, it is possible to improve the angle of view characteristics of the transmission screen 10 provided with the microlens substrate 1. In particular, in this case, it is possible to improve the angle of view characteristics in both the horizontal and vertical directions of the transmission screen 10 provided with the microlens substrate 1.

Moreover, in the case where the depth of each of the concave portions 61 is defined as D (μm) and the length of each of the concave portions 61 in a short axis direction thereof is defined as L₁ (μm), it is preferable that D and L₁ satisfy the relation: 0.3≦L₁/D≦5. More preferably D and L₁ satisfy the relation: 0.9≦L₁/D≦1.4, and further more preferably D and L₁ satisfy the relation: 1.2≦L₁/D≦1.4. In the case where D and L₁ satisfy such relation as described above, it is possible to improve the angle of view characteristics of the microlens substrate 1 to be manufactured particularly while preventing moire due to interfere of light from being generated effectively.

Further, the plurality of concave portions 61 are arranged on the outer peripheral surface of the substrate 6 with concave portions in a houndstooth check manner. By arranging the plurality of concave portions 61 in this way, it is possible to prevent disadvantage such as moire from being generated effectively. On the other hand, for example, in the case where the concave portions 61 are arranged on the outer peripheral surface of the substrate 6 with concave portions in a square lattice manner or the like, it is difficult to prevent disadvantage such as moire from being generated sufficiently. Further, in the case where the concave portions 61 are arranged on the outer peripheral surface of the substrate 6 with concave portions in a random manner, it is difficult to improve the share of the concave portions 61 in a usable area in which the concave portions 61 are formed sufficiently, and it is difficult to improve light transmission into the microlens substrate and/or the substrate with concave portions (that is, light use efficiency) sufficiently. In addition, the obtained image becomes dark.

Furthermore, although the concave portions 61 are arranged on the substrate 6 with concave portions in a houndstooth check manner when viewed from above the one major surface of the substrate 6 with concave portions as described above, it is preferable that a first column of concave portions 61 is shifted by a half pitch of each of the concave portions 61 in a short axis direction thereof with respect to a second column of concave portions 61 which is adjacent to the first column of concave portions 61 when viewed from above the one major surface of the substrate 6 with concave portions. This makes it possible to improve the angle of view characteristics particularly while preventing moire due to interfere of light from being generated effectively.

As described above, by defining the shape, arrangement pattern, share and the like of the concave portions 61 with which the substrate 6 with concave portions is provided strictly, it is possible to define the shape, arrangement pattern, share and the like of the microlenses 21 with which the microlens substrate 1 to be manufactured using the substrate 6 with concave portions is provided as convex lenses strictly. As a result, it is possible to improve the angle of view characteristics of a screen provided with the microlens substrate 1 particularly while preventing moire from being generated due to interference of light effectively.

In this regard, in the above explanation, it has been described that each of the concave portions 61 has substantially the same shape (size) as that of each of the microlenses 21 with which the microlens substrate 1 is provided, and the concave portions 61 have substantially the same arrangement pattern as that of the microlenses 21. However, for example, in the case where the constituent material of the main substrate 2 of the microlens substrate 1 tends to contract easily (that is, in the case where the resin material constituting the main substrate 2 is contracted by means of solidification or the like), the shape (and size), share or the like with respect to each of the microlenses 21 with which the microlens substrate 1 is provided an the concave portions 61 with which the substrate 6 with concave portions (for forming microlenses 21) is provided may be different from each other in view of the percentage of contraction or the like.

Next, the method of manufacturing the substrate 6 with concave portions according to the invention will now be described with reference to FIG. 5. In this regard, although a plurality of concave portions 61 for forming microlenses 21 are actually formed in a base substrate 7, in order to make the explanation understandable, a part of the base substrate 7 is shown so as to be emphasized in FIG. 5.

First, a base substrate 7 is prepared in manufacturing the substrate 6 with concave portions.

It is preferable that a base material having a substantially column shape or substantially cylinder shape is used for the base substrate 7. Further, it is also preferable that a base material with a surface cleaned by washing or the like is used for the base substrate 7.

Although soda-lime glass, crystalline glass, quartz glass, lead glass, potassium glass, borosilicate glass, alkali-free glass and the like may be mentioned as for a constituent material for the base substrate 7, soda-lime glass and crystalline glass (for example, neoceram or the like) are preferable among them. By the use of soda-lime glass, crystalline glass or alkali-free glass, it is easy to process the material for the base substrate 7, and it is advantageous from the viewpoint of a manufacturing cost of the substrate 6 with concave portions because soda-lime glass or crystalline glass is relatively inexpensive.

<A1> As shown in FIG. 5A, a mask 8 is formed on the surface of the prepared base substrate 7 (mask formation process). Then, a back surface protective film 89 is formed on the back surface of the base substrate 7 (that is, the surface side opposite to the surface on which the mask 8 is formed). Needless to say, the mask 8 and the back surface protective film 89 may be formed simultaneously.

The constituent material of the mask 8 is not particularly limited, for example, metals such as Cr, Au, Ni, Ti, Pt, and the like, metal alloys containing two or more kinds of metals selected from these metals, oxides of these metals (metal oxides), silicon, resins, and the like may be mentioned.

Further, the mask 8 may be, for example, one having a substantially even composition, or a laminated structure by a plurality of layers.

As described above, the configuration of the mask 8 is not particularly limited, and it is preferable that the mask 8 has a laminated structure constructed from a layer formed of chromium as a main material and a layer formed of chromium oxide as a main material. The mask 8 having such a structure has excellent stability with respect to various etchants having various structures (that is, it is possible to protect the base substrate 7 more surely at an etching process (as will be described later)), and it is possible to form the openings (initial holes 81) each having a desired shape easily and surely by means of irradiation with laser beams or the like as will be described later. Further, in the case where the mask 8 has such a structure as described above, a solution containing ammonium hydrogen difluoride (NH₄HF₂), for example, may be appropriately used as an etchant at the etching process (described later). Since a solution containing ammonium hydrogen difluoride is not poison, it is possible to prevent its influence on human bodies during work and on the environment more surely. Moreover, the mask 8 having such a structure makes it possible to reduce internal stress of the mask 8 effectively, and such a mask 8 has excellent adhesion (that is, adhesion of the mask 8 to the base substrate 7 at the etching process, in particular) to the base substrate 7, in particular. For these reasons, by using the mask 8 having the structure described above, it is possible to form concave portions 61 each having a desired shape easily and surely.

The method of forming the mask 8 is not particularly limited. In the case where the mask 8 is constituted from any of metal materials (including metal alloys) such as Cr and Au or metal oxides such as chromium oxide, the mask 8 can be suitably formed by means of an evaporation method, a sputtering method, or the like, for example. On the other hand, in the case where the mask 8 is formed of silicon, the mask 8 can be suitably formed by means of a sputtering method, a CVD method, or the like, for example.

Although the thickness of the mask 8 also varies depending upon the material constituting the mask 8, it is preferable that the thickness of the mask 8 is in the range of 0.01 to 2.0 μm, and more preferably it is in the range of 0.03 to 0.2 μm. If the thickness of the mask 8 is below the lower limit given above, there may be a possibility to deform the shapes of the initial holes (openings) 81 formed at the initial hole formation process (or openings formation process, which will be described later) depending upon the constituent material of the mask 8 or the like. In addition, there is a possibility that sufficient protection for the masked portion of the base substrate 7 cannot be obtained during a wet etching process at the etching step (described later). On the other hand, if the thickness of the mask 8 is over the upper limit given above, in addition to the difficulty in formation of the initial holes 81 that penetrate the mask 8 at the initial hole formation process (described later), there will be a case in which the mask 8 tends to be easily removed due to internal stress thereof depending upon the constituent material or the like of the mask 8.

The back surface protective film 89 is provided for protecting the back surface of the base substrate 7 at the subsequent processes. Erosion, deterioration or the like of the back surface of the base substrate 7 can be suitably prevented by means of the back surface protective film 89. Since the back surface protective film 89 has, for example, the same configuration as that of the mask 8, it may be provided in a manner similar to the formation of the mask 8 simultaneously with the formation of the mask 8.

<A2> Next, as shown in FIG. 5B, the plurality of initial holes 81 that will be utilized as mask openings at the etching process (described later) are formed in the mask 8 (initial hole formation process). The method of forming the initial holes 81 is not particularly limited, but it is preferable that the initial holes 81 are formed by the irradiation with laser beams. This makes it possible to form the initial holes 81 each having a desired shape, which are arranged in a desired pattern, easily and accurately. As a result, it is possible to control the shape of each of the concave portions 61, the arrangement pattern thereof, or the like more surely. Further, by forming the initial holes 81 by means of the irradiation with laser beams, it is possible to manufacture the substrate 6 with concave portions at high productivity. In particular, the concave portions can be easily formed on a relatively large-sized substrate. Moreover, in the case where the initial holes 81 are formed by means of irradiation with laser beams, by controlling the irradiation conditions thereof, it is possible to form only the initial holes 81 without forming initial concave portions 71 (will be described later), or it is possible to form the initial concave portions 71 in which variation in shape, size and depth thereof is made to be small easily and surely in addition to the initial holes 81. Furthermore, by forming the initial holes 81 in the mask 8 by means of irradiation with laser beams, it is possible to form the openings (initial holes 81) in the mask 8 at a low cost easily compared with the case of forming openings in a mask by means of a conventional photolithography method.

Further, in the case where the initial holes 81 are formed by means of the irradiation with laser beams, the kind of laser beam to be used is not particularly limited, but a ruby laser, a semiconductor laser, a YAG laser, a femtosecond laser, a glass laser, a YVO₄ laser, a Ne—He laser, an Ar laser, a carbon dioxide laser, an excimer laser or the like may be mentioned. Moreover, a waveform of a laser such as SHG (second-harmonic generation), THG (third-harmonic generation), FHG (fourth-harmonic generation) or the like may be utilized.

When the initial holes 81 are formed in the mask 8, as shown in FIG. 5B, the initial concave portions 71 may also be formed in the base substrate 7 by removing parts of the surface of the base substrate 7 in addition to the initial holes 81. This makes it possible to increase contact area of the base substrate 7 with the etchant when subjecting the base substrate 7 with the mask 8 to the etching process (described later), whereby erosion can be started suitably. Further, by adjusting the depth of each of the initial concave portions 71, it is also possible to adjust the depth of each of the concave portions 61 (that is, the maximum thickness of the lens (microlens 21)). Although the depth of each of the initial concave portions 71 is not particularly limited, it is preferable that it is 5.0 μm or less, and more preferably it is in the range of about 0.1 to 0.5 μm. In the case where the formation of the initial holes 81 is carried out by means of the irradiation with laser beams, it is possible to surely reduce variation in the depth of each of the plurality of initial concave portions 71 formed together with the initial holes 81. This makes it possible to reduce variation in the depth of each of the concave portions 61 constituting a substrate 6 with concave portions, and therefore it is possible to reduce variation in the size and shape of each of the microlenses 21 in the microlens substrate 1 obtained finally. As a result, it is possible to reduce variation in the diameter, the focal distance, and the thickness of the lens of each of the microlenses 21, in particular.

The initial holes (openings) 81 to be formed at this process satisfy predetermined relation with respect to the concave portions to be formed at a subsequent step (that is, etching process). Namely, in the case where the depth of each of the concave portions 61 to be formed at the subsequent process in a direction perpendicular to the major surface of the base substrate 7 (that is, in the thickness direction of the substrate 6 with concave portions) is defined as D (μm) and the value obtained by dividing the difference between the length of each of the concave portions 61 to be formed in a long axis direction thereof (in a surface direction of the substrate 6 with concave portions) and the diameter of each of the formed openings (initial holes) 81 by two is defined as S (μm), then D and S satisfy the relation: 0.90≦S/D≦1.40. In the case where D and S satisfy such relation, it is possible to manufacture the microlens substrate 1 provided with the microlenses 21 having an appropriate shape and arrangement as described above. By utilizing such a microlens substrate 1 in a transmission screen 10 and/or a rear projection 300, it is possible to prevent moire from being generated due to interference of light efficiently, and therefore, such a microlens substrate 1 can be used to manufacture a transmission screen 10 and a rear projection 300 having excellent angle of view characteristics suitably. In this way, in the invention, although D and S have only to satisfy the relation: 0.90≦S/D≦1.40, it is preferable that D and S satisfy the relation: 0.92≦S/D≦1.20, and more preferably D and S satisfy the relation: 0.93≦S/D≦1.04. The initial holes 81 to be formed at this process are formed so as to have predetermined arrangement and predetermined density in consideration of the shape, arrangement, share and the like of the concave portions 61 to be formed at the subsequent process.

The shape and size of each of the initial holes 81 to be formed At the present process is not particularly limited. In the case where each of the initial holes 81 is a substantially circular shape, it is preferable that the diameter of each of the initial holes 81 is in the range of 0.8 to 20 μm. More preferably it is in the range of 1.0 to 10 μm, and further more preferably it is in the range of 1.5 to 4 μm. In the case where the diameter of each of the initial holes 81 is restricted within the above ranges, it is possible to form the concave portions 61 each having the shape as described above at an etching process (will be described later) surely. On the other hand, in the case where each of the initial holes 81 is a flat shape such as a substantially elliptic shape, it is possible to substitute the length thereof in the short axis direction (that is, width thereof) for the diameter thereof. Namely, in the case where each of the initial holes 81 to be formed at the present process is the substantially elliptic shape, the width of each of the initial holes 81 (the length in the short axis direction thereof) is not particularly limited, but the width of each of the initial holes 81 is in the range of 0.8 to 20 μm. More preferably it is in the range of 1.0 to 10 μm, and further more preferably it is in the range of 1.5 to 4 μm. In the case where the width of each of the initial holes 81 is restricted within the above ranges, it is possible to form the concave portions 61 each having the shape as described above at an etching process (will be described later) surely.

Further, in the case where each of the initial holes 81 to be formed at the present process is the substantially elliptic shape, the length of each of the initial holes 81 (the length in the long axis direction thereof) is not particularly limited, but the width of each of the initial holes 81 is in the range of 0.9 to 30 μm. More preferably it is in the range of 1.5 to 15 μm, and further more preferably it is in the range of 2.0 to 6 μm. In the case where the width of each of the initial holes 81 is restricted within the above ranges, it is possible to form the concave portions 61 each having the shape as described above at an etching process (will be described later) more surely.

Further, other than by means of the irradiation with laser beams, the initial holes 81 may be formed in the formed mask 8 by, for example, previously arranging foreign objects on the base substrate 7 with a predetermined pattern when the mask 8 is formed on the base substrate 7, and then forming the mask 8 on the base substrate 7 with the foreign objects to form defects in the mask 8 by design so that the defects are utilized as the initial holes 81.

<A3> Next, as shown in FIG. 5C, a large number of concave portions 61 are formed in the base substrate 7 by subjecting the base substrate 7 to the etching process using the mask 8 in which the initial holes 81 are formed (etching process). The etching method is not particularly limited, and as for the etching method, a wet etching process, a dry etching process and the like may be mentioned, for example. In the following explanation, the case of using the wet etching process will be described as an example.

By subjecting the base substrate 7 covered with the mask 8 in which the initial holes 81 are formed to the wet etching process, as shown in FIG. 5C, the base substrate 7 is eroded from the portions where no mask 8 is present, whereby a large number of concave portions 61 are formed in the base substrate 7. As mentioned above, since the initial holes 81 formed in the mask 8 are arranged in a houndstooth check manner, the concave portions 61 to be formed are also arranged on the surface of the base substrate 7 in a houndstooth check manner.

Further, in the present embodiment, the initial concave portions 71 are formed on the surface of the base substrate 7 when the initial holes 81 are formed in the mask 8 at step <A2>. This makes the contact area of the base substrate 7 with the etchant increase during the etching process, whereby erosion can be made to start suitably. Moreover, the concave portions 61 can be formed suitably by employing the wet etching process. In the case where an etchant containing, for example, ammonium hydrogen difluoride is utilized for an etchant, the base substrate 7 can be eroded more selectively, and this makes it possible to form the concave portions 61 suitably.

In the case where the mask 8 is mainly constituted from chromium (that is, the mask 8 is formed of a material containing Cr as a main material thereof), a solution of ammonium hydrogen difluoride is particularly suited as a hydrofluoric acid-based etchant. Since a solution containing ammonium hydrogen difluoride is not poison, it is possible to prevent its influence on human bodies during work and on the environment more surely. Further, in the case where the solution of ammonium hydrogen difluoride is used as an etchant, for example, hydrogen peroxide may be contained in the etchant. This makes it possible to accelerate the etching speed.

Further, the wet etching process can be carried out with simpler equipment than that in the dry etching process, and it allows the processing for a larger number of base substrates 7 at a time. This makes it possible to enhance productivity of the substrate 6 with concave portions, and it is possible to provide the substrate 6 with concave portions at a lower cost.

<A4> Next, the mask 8 is removed as shown in FIG. 5D (mask removal process). At this time, the back surface protective film 89 is also removed along with the mask 8. In the case where the mask 8 is constituted from the laminated structure constructed from the layer formed of chromium as a main material and the layer formed of chromium oxide as a main material as described above, the removal of the mask 8 can be carried out by means of an etching process using a mixture of ceric ammonium nitrate and perchloric acid, for example.

As a result of the processing in the above, as shown in FIGS. 5D and 4, a substrate 6 with concave portions in which a large number of concave portions 61 are formed in the base substrate 7 in a houndstooth check manner is obtained.

The method of forming the plurality of concave portions 61 on the surface of the base substrate 7 in a houndstooth check manner is not particularly limited. In the case where the concave portions 61 are formed by means of the method as mentioned above, that is, the method of forming the concave portions 61 in the base substrate 7 by forming the initial holes 81 in the mask 8 by means of the irradiation with laser beams and then subjecting the base substrate 7 to the etching process using the mask 8, it is possible to obtain the following effects.

Namely, by forming the initial holes 81 in the mask 8 by means of the irradiation with laser beams, it is possible to form openings (initial holes 81) in a predetermined pattern in the mask 8 easily and inexpensively compared with the case of forming the openings in the mask 8 by means of the conventional photolithography method. This makes it possible to enhance productivity of the substrate 6 with concave portions, whereby it is possible to provide the substrate 6 with concave portions at a lower cost.

Further, according to the method as described above, it is possible to carry out the processing for a large-sized substrate easily. Also, according to the method, in the case of manufacturing such a large-sized substrate, there is no need to bond a plurality of substrates as the conventional method, whereby it is possible to eliminate the appearance of seams of bonding. This makes it possible to manufacture a high quality large-sized substrate 6 with concave portions for forming microlenses 21 (that is, microlens substrate 1) by means of a simple method at a low cost.

Further, in the case of forming the initial holes 81 by means of the irradiation of laser beams, it is possible to control the shape and size of each of the initial holes 81 to be formed, arrangement thereof, and the like easily and surely.

Next, a method of manufacturing the microlens substrate 1 using the substrate 6 with concave portions will now be described.

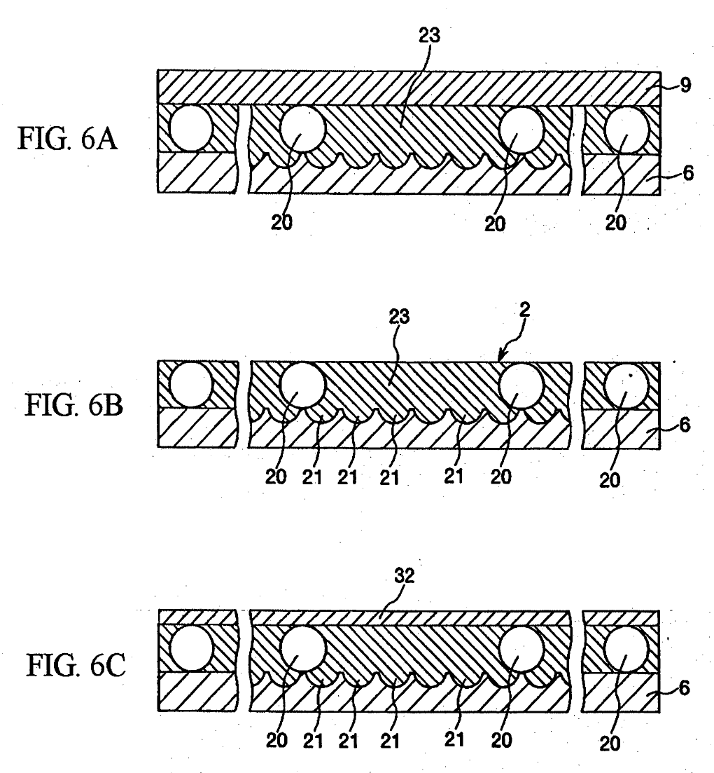

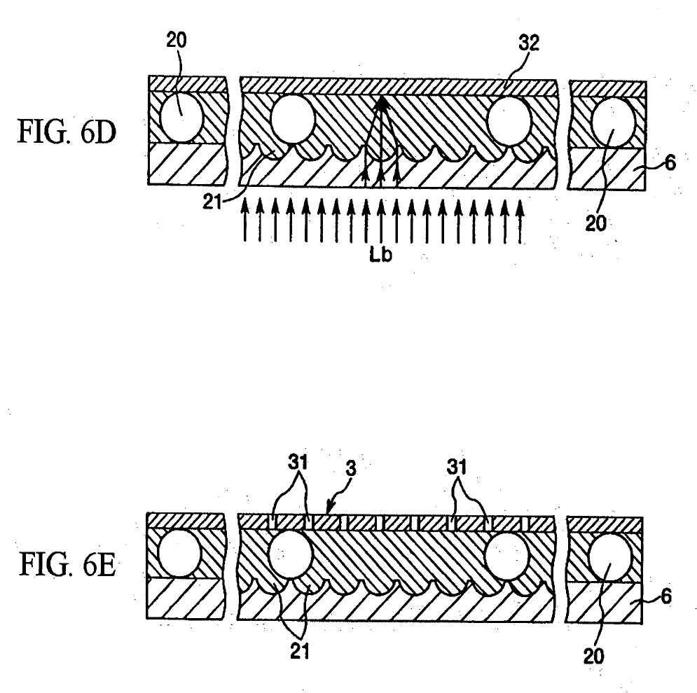

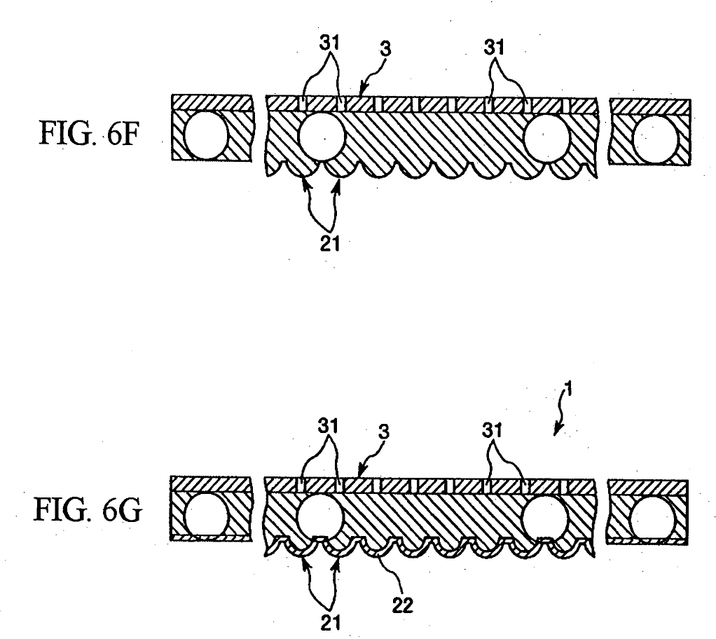

FIG. 6 is a longitudinal cross-sectional view which schematically shows one example of a method of manufacturing the microlens substrate 1 shown in FIG. 1. Now, in following explanations using FIG. 6, for convenience of explanation, a lower side and an upper side in FIG. 6 are referred to as “light incident side” and “light emission side”, respectively.

<B1> As shown in FIG. 6A, a resin material 23 having fluidity (for example, a resin material 23 at a softened state, a non-polymerized (uncured) resin material 23) is supplied to the surface of the substrate 6 with concave portions for forming microlenses 21 on which the concave portions 61 are formed, and the resin material 23 is then pressed by means of a flat plate 9. In particular, in the present embodiment, the resin material 23 is pressed (or pushed) by means of the flat plate 9 while spacers 20 are provided between the substrate 6 with concave portions and the flat plate 9. Thus, it is possible to control the thickness of the formed microlens substrate 1 more surely, and this makes it possible to control the focal points of the respective microlenses 21 in the microlens substrate 1 finally obtained more surely. In addition, it is possible to prevent disadvantage such as color heterogeneity from being generated more efficiently.

Each of the spacers 20 is formed of a material having an index of refraction nearly equal to that of the resin material 23 (the resin material 23 at a solidified state). By using the spacers 20 formed of such a material, it is possible to prevent the spacers 20 from having a harmful influence on the optical characteristics of the obtained microlens substrate 1 even in the case where the spacers 20 are arranged in portions in each of which any concave portion 61 of the substrate 6 with concave portions is formed. This makes it possible to provide a relatively large number of spacers 20 in a wide region of one major surface of the substrate 6 with concave portions. As a result, it is possible to get rid of the influence due to flexure of the substrate 6 with concave portions and/or the flat plate 9, or the like efficiently, and this makes it possible to control the thickness of the obtained microlens substrate 1 more surely.

Although the spacers 20 are formed of the material having an index of refraction nearly equal to that of the resin material 23 (the resin material 23 at a solidified state) as described above, more specifically, it is preferable that the absolute value of the difference between the absolute index of refraction of the constituent material of the spacer 20 and the absolute index of refraction of the resin material 23 at a solidified state is 0.20 or less, and more preferably it is 0.10 or less. Further more preferably it is 0.20 or less, and most preferably the spacer 20 is formed of the same material as that of the resin material 23 at a solidified state.

The shape of each of the spacers 20 is not particularly limited. It is preferable that the shape of each of the spacers 20 is a substantially spherical shape or a substantially cylindrical shape. In the case where each of the spacers 20 has such a shape, it is preferable that the diameter of the spacer 20 is in the range of 10 to 300 μm, and more preferably it is in the range of 30 to 200 μm. Furthermore preferably, it is in the range of 30 to 170 μm.

In this regard, in the case of using the spacers 20 as described above, the spacers 20 may be provided between the substrate 6 with concave portions and the flat plate 9 when solidifying the resin material 23. Thus, the timing to supply the spacers 20 is not particularly limited. Further, for example, a resin material 23 in which the spacers 20 are dispersed in advance may be utilized as a resin material to be supplied onto the surface of the substrate 6 with concave portions on which the concave portions 61 are formed, or the resin material 23 may be supplied thereon while the spacers 20 are provided on the surface of the substrate 6 with concave portions. Alternatively, the spacers 20 may be supplied onto the surface of the substrate 6 with concave portions after supplying the resin material 23 thereto.

Further, prior to the supply of the resin material 23 and the pressing process by means of the flat plate 9, a mold release agent or the like may be applied onto the surface of the substrate 6 with concave portions on which the plurality of concave portions 61 are formed and/or the surface of the flat plate 9 with which the resin material 23 is pressed. This makes it possible to separate the microlens substrate 1 from the substrate 6 with concave portions and the flat plate 9 easily and surely at the following steps.

<B2> Next, the resin material 23 is solidified (in this regard, including hardened (polymerized)), and then the flat plate 9 is removed (see. FIG. 6B). In this way, the main substrate 2 provided with the plurality of microlenses 21 (in particular, microlenses 21 which satisfy the conditions as described above such as shape, arrangement and the like) constituted from the resin material 23 filled in the plurality of concave portions 61 each of which serves as a convex lens is obtained. In the case where the solidification of the resin material 23 is carried out by being hardened (polymerized), the method thereof is not particularly limited, and it is appropriately selected according to the kind of the resin material. For example, irradiation with light such as ultraviolet rays, heating, electron beam irradiation, or the like may be mentioned.

<B3> Next, a process that a black matrix 3 is formed on the light emission surface of the main substrate 2 manufactured as described above will be described.

First, as shown in FIG. 6C, a positive type photopolymer 32 having light shielding (blocking) effect is supplied onto the light emission surface of the main substrate 2. As the method of supplying the positive type photopolymer 32 onto the light emission surface of the main substrate 2, for example, various types of coating methods such as a dip coat method, a doctor blade method, a spin coat method, a blush coat method, a spray coating, an electrostatic coating, an electrodeposition coating, a roll coater, and the like can be utilized. The positive type photopolymer 32 may be constituted from a resin having light shielding (blocking) effect, or may be one in which a material having light shielding (blocking) effect is dispersed or dissolved to a resin material having low light shielding (blocking) effect. Heat treatment such as a pre-bake process, for example, may be carried out after supplying the positive type photopolymer 32 if needed.

<B4> Next, as shown in FIG. 6D, light Lb for exposure is irradiated to the main substrate 2 in a direction perpendicular to the light incident surface of the main substrate 2. The irradiated light Lb for exposure is condensed by passing through each of the microlenses 21. The positive type photopolymer 32 in the vicinity of the focal point f of each of the microlenses 21 is exposed, and the positive type photopolymer 32 corresponding to portions other than the vicinity of the focal points f is not exposed or slightly exposed (that is, the degree of exposure is small). In this way, only the positive type photopolymer 32 in the vicinity of the respective focal points f is exposed.

The development is then carried out. In this case, since the photopolymer 32 is a positive type photopolymer, the exposed photopolymer 32 in the vicinity of the respective focal points f is melt and removed by the development. As a result, as shown in FIG. 6E, the black matrix 3 in which the openings 31 are formed on the portions corresponding to the optical axes L of the microlenses 22 is provided. The developing method may be selected arbitrarily depending on composition of the positive type photopolymer 32 or the like. For example, the development of the positive type photopolymer 32 in the present embodiment can be carried out using an alkaline aqueous solution such as a solution of potassium hydroxide or the like.

In this way, in the method of manufacturing a microlens substrate 1 of the present embodiment, since the black matrix 3 is formed by irradiating the photopolymer 32 with the light for exposure condensed by the plurality of microlenses 21, it is possible to form the black matrix 3 with simpler process compared with the case of using a photolithography technology, for example.

Further, heat treatment such as a post-bake process may be carried out after exposing the positive type photopolymer 32 if needed.

<B5> Next, the main substrate 2 is released from the substrate 6 with concave portions (see FIG. 6F). In this way, by removing the substrate 6 with concave portions from the main substrate 2, it is possible to use the substrate 6 with concave portions repeatedly when manufacturing the main substrate 2 (that is, microlens substrate 1), and this makes it possible to reduce the manufacturing costs for the main substrate 2, and to heighten the stability of quality of the main substrate 2 (microlens substrate 1) to be manufactured.

<B6> Then, by supplying a coloring liquid onto the main substrate 2 that has been released from the substrate 6 with concave portions, a colored portion 22 is formed thereon, whereby a microlens substrate 1 is obtained (see FIG. 6G).

The coloring liquid is not particularly limited, and in the present embodiment, the coloring liquid is one containing a coloring agent and benzyl alcohol. The invention found that it is possible to carry out the coloring of the main substrate easily and surely by using such a coloring liquid. In particular, according to the processes, it is possible to subject a main substrate 2 formed of a material such as an acrylic based resin which it is difficult to color in a conventional coloring method to a coloring process easily and surely. It is thought that this is for the following reasons.

Namely, by using the coloring liquid containing benzyl alcohol, the benzyl alcohol in the coloring liquid penetrates the main substrate 2 deeply and diffuses therein, whereby the bonding of molecules (the bonding between the molecules) constituting the main substrate 2 is loosened, and spaces in which the coloring agent is to penetrate are secured. The benzyl alcohol and the coloring agent in the coloring liquid are replaced, by which the coloring agent is held in the spaces (which can be likened to seats for the coloring agent (coloring seats)), and therefore, the surface of the main substrate 2 is colored.

Further, by using the coloring liquid as described above, it is possible to form the colored portion 22 having an even thickness easily and surely. In particular, even though a main substrate (that is, work) to be colored is one in which a minute structure such as microlenses is provided on the surface thereof (one in which a cycle of unevenness in a two-dimensional direction of the surface thereof is small) or one in which the region to be colored is a large area, it is possible to form the colored portion 22 with an even thickness (that is, without color heterogeneity).

As the method of supplying the coloring liquid onto the light incident surface of the main substrate 2, for example, various types of coating methods such as a doctor blade method, a spin coat method, a blush coat method, a spray coating, an electrostatic coating, an electrodeposition coating, printing, a roll coater, and a dipping method in which the main substrate 2 is immersed (soaked) in the coloring liquid, and the like may be mentioned. The dipping method (in particular, dip dyeing) is suitable among these methods. This makes it possible to form the colored portion 22 (in particular, the colored portion 22 having an even thickness) easily and surely. Further, in particular, in the case where the coloring liquid is supplied onto the main substrate 2 by means of dip dyeing, it is possible to color even a main substrate 2 formed of a material such as an acrylic based resin which it is difficult to color in a conventional coloring method easily and surely. It is thought that this is because the dye that can be used for dip dyeing has high affinity to an ester group (ester bonding) that acrylic based resin or the like has.

It is preferable that the coloring liquid supplying step is carried out while the coloring liquid and/or the main substrate 2 are heated at the range of 60 to 100° C. This makes it possible to form the colored portion 22 efficiently while preventing a harmful influence (for example, deterioration of the constituent material of the main substrate 2) on the main substrate 2 on which the colored portion 22 is to be formed from being generated sufficiently.

Further, the coloring liquid supplying step may be carried out while the ambient pressure is heightened (with application of pressure). This makes it possible to accelerate the penetration of the coloring liquid into the inside of the main substrate 2, and as a result, it is possible to form the colored portion 22 efficiently with a short time.

In this regard, the step of supplying the coloring liquid may be carried out repeatedly (that is, multiple times) if needed (for example, in the case where the thickness of the colored portion 22 to be formed is relatively large). Further, the main substrate 2 may be subjected to heat treatment such as heating, cooling and the like, irradiation with light, pressurization or decompression of the atmosphere, or the like after supplying the coloring liquid if needed. This makes it possible to accelerate the fixing (stability) of the colored portion 22.

Hereinafter, the coloring liquid used at the present step will be described in detail.

The content by percentage of the benzyl alcohol in the coloring liquid is not particularly limited. It is preferable that the content by percentage of the benzyl alcohol is in the range of 0.01 to 10.0% by weight. More preferably it is in the range of 0.05 to 8.0% by weight, and further more preferably it is in the range of 0.1 to 5.0% by weight. In the case where the content by percentage of benzyl alcohol is restricted within the above ranges, it is possible to form the suitable colored portion 22 easily and surely while preventing a harmful influence (such as deterioration of the constituent material of the main substrate 2) on the main substrate 2 on which the colored portion 22 is to be formed from being generated more efficiently.

The coloring agent contained in the coloring liquid may be any one such as various dyes and various pigments, but it is preferable that the coloring agent is a die. More preferably it is a disperse dye and/or a cationic dye, and further more preferably it is a disperse dye. This makes it possible to form the colored portion 22 efficiently while preventing a harmful influence on the main substrate 2 on which the colored portion 22 is to be formed (for example, deterioration of the constituent material of the main substrate 2) from being generated sufficiently. In particular, it is possible to color even a main substrate 2 formed of a material such as an acrylic based resin which it is difficult to color in a conventional coloring method easily and surely. It is thought that this is because it is easy to color such a material because the coloring agent as described above uses ester functions (ester bonding) that acrylic based resin or the like has as the coloring seats.

As described above, although the coloring liquid used in the present embodiment contains at least the coloring agent and benzyl alcohol, it is preferable that the coloring liquid further contains at least one compound selected from the benzophenone based compound and the benzotriazole based compound and benzyl alcohol. This makes it possible to form the colored portion 22 more efficiently while preventing a harmful influence (for example, deterioration of the constituent material of the main substrate 2) on the main substrate 2 on which the colored portion 22 is to be formed from being generated sufficiently. It is thought that this is for the following reasons.

Namely, by using the coloring liquid containing benzyl alcohol, and at least one kind of compound selected from a benzophenone based compound and a benzotriazole based compound (hereinafter, benzyl alcohol, the benzophenone based compound and the benzotriazole based compound are collectively referred to as “additives”), the additives in the coloring liquid penetrates the main substrate 2 and diffuses therein, whereby the bonding of molecules (the bonding between the molecules) constituting the main substrate 2 is loosened, and spaces in which the coloring agent is to penetrate are secured. The additives and the coloring agent are replaced by which the coloring agent is held in the spaces (which can be likened to seats for the coloring agent (coloring seats)), and therefore, the surface of the main substrate 2 is colored. It is thought that this is because, by using the at least one compound selected from the benzophenone based compound and the benzotriazole based compound and benzyl alcohol together, they interact with each other in a complementary manner, and the coloring by the coloring liquid becomes good.

As for the benzophenone based compound, a compound having a benzophenone skeleton, its tautomers, or these inductors (for example, addition reaction products, substitution reaction products, reductive reaction products, oxidation reaction products and the like) can be utilized.

As for such compounds, for example, benzophenone, 2,4-dihydroxybenzophenone, 2-hydroxy-4-methoxybenzophenone, 2,2′-dihydroxy-4,4′-dimethoxybenzophenone, 2,2′,4,4-tetrahydroxybenzophenone, 2-hydroxy-4-octylbenzophenone, 4-benzyloxy-2-hydroxybenzophenone, benzophenone anil, benzophenone oxime, benzophenone chloride(α,α′-dichlorodiphenylmethane) and the like may be mentioned. The compound that has benzophenone skeleton is preferable among these compounds, and more preferably the compound is any one of 2,2′-dihydroxy-4,4′-dimethoxybenzophenone and 2,2′,4,4-tetrahydroxybenzophenone. By using such a benzophenone based compound, the effects as described above appear remarkably.

Further, as for the benzotriazole based compound, a compound having a benzotriazole skeleton, its tautomers, or these inductors (for example, addition reaction products, substitution reaction products, reductive reaction products, oxidation reaction products and the like) can be utilized.

As for such compounds, for example, benzotriazole, 2-(2-hydroxy-5-methylphenyl)-2H-benzotriazole, 2-(2-hydroxy-4-octyloxyphenyl)-2H-benzotriazole and the like may be mentioned. The compound that has benzotriazole skeleton is preferable among these compounds, and more preferably the compound is any one of 2-(2-dihydroxy-5-methylphenyl)-2H-benzotriazole and 2-(2-hydroxy-4-octyloxyphenyl)-2H-benzotriazole. By using such a benzotriazole based compound, the effects as described above appear remarkably.

In the case where the benzophenone based compound and/or the benzotriazole based compound is contained in the coloring liquid, the total content by percentage of the benzophenone based compound and the benzotriazole based compound in the coloring liquid is not particularly limited. It is preferable that the total content by percentage of the benzophenone based compound and the benzotriazole based compound in the coloring liquid is in the range of 0.001 to 10.0% by weight. More preferably it is in the range of 0.005 to 5.0% by weight, and further more preferably it is in the range of 0.01 to 3.0% by weight. In the case where the total content by percentage of the benzophenone based compound and the benzotriazole based compound is restricted within the above ranges, it is possible to form the suitable colored portion 22 easily and surely while preventing a harmful influence (such as deterioration of the constituent material of the main substrate 2) on the main substrate 2 on which the colored portion 22 is to be formed from being generated more efficiently.

Further, in the case where the benzophenone based compound and/or the benzotriazole based compound is contained in the coloring liquid, and the content by percentage of the benzophenone-based compound in the coloring liquid is defined as X (% by weight) and the total content by percentage of the benzophenone based compound and the benzotriazole based compound in the coloring liquid is defined as Y (% by weight), then it is preferable that X and Y satisfy the relation: 0.001≦X/Y≦10000. More preferably X and Y satisfy the relation: 0.05≦X/Y≦1000, and further more preferably X and Y satisfy the relation: 0.25≦X/Y≦500. In the case where X and Y satisfy the relations as described above, synergistic effects by using the benzophenone based compound and/or the benzotriazole based compound together with benzyl alcohol are exerted more remarkably. In addition, it is possible to form the suitable colored portion 22 with a high speed easily and surely while preventing a harmful influence (such as deterioration of the constituent material of the main substrate 2) on the main substrate 2 on which the colored portion 22 is to be formed from being generated more efficiently.

Further, it is preferable that the coloring liquid further contains benzyl alcohol and a surfactant. This makes it possible to disperse the coloring agent stably and evenly even under the conditions in which benzyl alcohol exists. Even though the main material 2 onto which the coloring liquid is to be supplied is formed of a material such as an acrylic based resin that it is difficult to color in a conventional method, it is possible to color the main substrate 2 easily and surely. As for a surfactant, nonionic surfactants, anionic surfactants, cationic surfactants, ampholytic surfactants and the like may be mentioned. As for the nonionic surfactant, for example, ether based surfactants, ester based surfactants, ether ester based surfactants, nitrogenous based surfactants and the like may be mentioned. More specifically, polyvinyl alcohol, carboxymethylcellulose, polyethylene glycol, acrylic ester, methacrylic ester, and the like may be mentioned. Further, as for anionic surfactants, for example, various kinds of rosins, various kinds of carboxylates, various kinds of ester sulfates, various kinds of sulfonates, various kinds of ester phosphates, and the like may be mentioned. More specifically, gum rosin, polymerized rosin, disproportionated rosin, maleic rosin, fumaric rosin, maleic rosin pentaester, maleic rosin glycerolester, tristearate (for example, metal salt such as aluminum salt), distearate (for example, metal salt such as aluminum salt, barium salt), stearate (for example, metal salt such as calcium salt, lead salt, zinc lead salt), linolenate (for example, metal salt such as cobalt salt, manganese salt, lead salt, zinc salt), octanoate (for example, metal salt such as aluminum salt, calcium salt, cobalt salt), oleate (for example, metal salt such as calcium salt, cobalt salt), palmitate (metal salt such as zinc salt), naphthenate (for example, metal salt such as calcium salt, cobalt salt, manganese salt, lead salt, zinc salt), resinate (for example, metal salt such as calcium salt, cobalt salt, manganese salt, zinc salt), polyacrylate (for example, metal salt such as sodium salt), polymethacrylate (for example, metal salt such as sodium salt), polymaleate (for example, metal salt such as sodium salt), acrylate-maleate copolymer (for example, metal salt such as sodium salt), cellulose, dodecylbezenesulfonate (for example, metal salt such as sodium salt), alkylsulfonate salt, polystyrenesulfonate, (for example, (for example, metal salt such as sodium salt), alkyldiphenyletherdisulfonate (for example, metal salt such as sodium salt), and the like may be mentioned. Further, as for cationic surfactants, for example, various kinds of ammonium salts such as primary ammonium salt, secondary ammonium salt, tertiary ammonium salt, quaternary ammonium salt may be mentioned. More specifically, monoalkylamine salt, dialkylamine salt, trialkylamine salt, tetraalkylamine salt, benzalkonium salt, alkylpyridinium salt, imidazolium salt, and the like may be mentioned. Further, as for ampholytic surfactants, for example, various kinds of betaines such as carboxybetaine, sulfobetaine, various kinds of aminocarboxylic acids, various kinds of ester phosphate salts, and the like may be mentioned.

Hereinafter, a description will be given for a rear projection using the transmission screen described above.

FIG. 7 is a cross-sectional view which schematically shows a rear projection 300 to which the transmission screen 10 of the invention is applied. As shown in FIG. 7, the rear projection 300 has a structure in which a projection optical unit 310, a light guiding mirror 320 and a transmission screen 10 are arranged in a casing 340.

Since the rear projection 300 uses the transmission screen 10 that has excellent angle of view characteristics and light use efficiency as described above, it is possible to obtain image having excellent contrast. In addition, since the rear projection 300 has the structure as described above in the present embodiment, it is possible to obtain excellent angle of view characteristics and light use efficiency, in particular.

Further, since the microlenses 21 each having a substantially ellipse shape are arranged in a houndstooth check manner on the microlens substrate 1 described above, the rear projection 300 hardly generates problems such as moire, in particular.

As described above, it should be noted that, even though the method of manufacturing a substrate 6 with concave portions, the substrate 6 with concave portions, the microlens substrate 1, the transmission screen 10 and the rear projection 300 according to the invention have been described with reference to the preferred embodiments shown in the accompanying drawings, the invention is not limited to these embodiments. For example, each element (component) constituting the microlens substrate 1, the transmission screen 10 and the rear projection 300 may be replaced with one capable of performing the same or a similar function.

Further, in the embodiment described above, even though it has been described that the spacers 20 each having an index of refraction nearly equal to that of the resin material 23 (that is, the resin material 23 after solidification) are used as spacers, each of the spacers 20 having an index of refraction nearly equal to that of the resin material 23 (that is, the resin material 23 after solidification) is not required in the case where the spacers 20 are arranged only in the region where no concave portions 61 of the substrate 6 with concave portions are formed (unusable lens area). Moreover, the spacers 20 as described above do not always have to be utilized in manufacturing the microlens substrate 1.

Moreover, in the embodiment described above, even though it has been described that the resin material 23 is supplied onto the surface of the substrate 6 with concave portions, the microlens substrate 1 may be manufactured so that, for example, the resin material 23 is supplied onto the surface of the flat plate 9 and the resin material 23 is then pressed by the substrate 6 with concave portions.

Furthermore, in the embodiment described above, even though it has been described that at the initial hole formation step in the method of manufacturing the substrate 6 with concave portions the initial concave portions 71 was formed in the base substrate 7 in addition to the initial holes 81, there is no need to form such initial concave portions 71. By appropriately adjusting the formation conditions for the initial holes 81 (for example, energy intensity of a laser, the beam diameter of the laser, irradiation time or the like), it is possible to form the initial concave portions 71 each having a predetermined shape, or it is possible to selectively form only the initial holes 81 so that the initial concave portions 71 are not formed.

Further, in the embodiment described above, even though it has been described that the transmission screen 10 is provided with the microlens substrate 1 and the Fresnel lens 5, the transmission screen 10 of the invention need not be provided with the Fresnel lens 5 necessarily. For example, the transmission screen 10 may be constructed from only the microlens substrate 1 of the invention practically.

Furthermore, in the embodiments described above, even though it has been described that the microlens substrate 1 is a member constituting the transmission screen 10 or the rear projection 300, the microlens substrate 1 is not limited to one to be applied described above, and it may be applied to one for any use. Further, for example, the substrate 6 with concave portions itself may be used as a microlens substrate (that is, a microlens substrate provided with a plurality of microlenses as concave lenses).

Moreover, in the embodiments described above, even though it has been described that the microlens substrate 1 is used by being released from the substrate 6 with concave portions, the substrate 6 with concave portions may be used along with the microlens substrate 1 without being removed from a manufactured microlens substrate (in particular, it may be used as a component of an optical apparatus such as a transmission screen, rear projection and the like).

### EXAMPLE

<Manufacture of Microlens Substrate and Transmission Screen>

### Example 1

A substrate with concave portions that was provided with a plurality of concave portions for forming microlenses was manufactured in the following manner.

First, a soda-lime glass substrate having a rectangle shape of 1.2 m (lateral)×0.7 m (longitudinal) and a thickness of 4.8 mm was prepared.

The soda-lime glass substrate was soaked in cleaning liquid containing 4% by weight ammonium hydrogen difluoride and 8% by weight sulfuric acid to carry out a 6 μm etching process, thereby cleaning its surface. Then, cleaning with pure water and drying with nitrogen (N₂) gas (for removal of pure water) were carried out.

Next, a laminated structure of chromium/chromium oxide (that is, laminated structure in which a layer formed of chromium was laminated on the outer circumference of a layer formed of chromium oxide) was formed on one major surface of the soda-lime glass substrate by means of a spattering method. Namely, a mask and a back surface protective film each made of the laminated structure constructed from the layer formed of chromium and the layer formed of chromium oxide were formed on both surfaces of the soda-lime glass substrate. In this case, the thickness of the chromium layer is 0.03 μm, while the thickness of the chromium oxide layer is 0.01 μm.

Next, laser machining was carried out to the mask to form a large number of initial holes within a region of 113 cm×65 cm at the central part of the mask. In this regard, the laser machining was carried out by irradiating laser beams onto the soda-lime glass substrate on which the mask (the laminated structure of chromium/chromium oxide) has been covered via the mask having 360 pieces of openings by means of an excimer laser under the conditions of energy intensity of 600 mJ/cm². The beam diameter (spot diameter) and energy intensity at each spot of the laser beam irradiated onto the soda-lime glass substrate on which the mask has been covered were 2.0 μm and 1 mJ/cm². Further, the scanning speed in a main scanning direction of the excimer laser was set to 0.1 m/second.

In this way, the initial holes were formed in a houndstooth check pattern over the substantially entire region of the mask mentioned above. The diameter of each of the initial holes was 2.0 μm. Further, at this time, concave portions each having a depth of about 0.004 μm and a damaged layer (or affected layer) were formed on the surface of the soda-lime glass substrate.

Next, the soda-lime glass substrate was subjected to a wet etching process, thereby forming a large number of concave portions (concave portions for forming microlenses) on the major surface of the soda-lime glass substrate. The shape of each of the concave portions was a substantially elliptic shape (flat shape) when viewed from above the major surface of the soda-lime glass substrate. The large number of concave portions thus formed had substantially the same shape as each other. The length of each of the formed concave portions in the short axis direction (diameter) thereof, the length of each of the formed concave portions in the long axis direction thereof, the radius of curvature and depth of each of the formed concave portions were 54 μm, 79.5 μm, 40 μm and 37.0 μm, respectively. Further, the share of the concave portions in a usable area in which the concave portions were formed was 97%.

In this regard, an aqueous solution containing 4% by weight ammonium hydrogen difluoride and 4% by weight sulfuric acid was used for the wet etching process as an etchant, and the soak time of the substrate was 125 minutes.

Next, the mask and the back surface protective film were removed by carrying out an etching process using a mixture of ceric ammonium nitrate and perchloric acid. Then, cleaning with pure water and drying with N₂ gas (removal of pure water) were carried out.

In this way, the substrate with concave portions corresponding to the microlens substrate as shown in FIG. 2 in which the large number of concave portions for forming microlenses were arranged in a houndstooth check manner on the major surface of the soda-lime glass substrate was obtained. A ratio of an area occupied by all the concave portions in the obtained substrate with concave portions in a usable area where the concave portions were formed with respect to the entire usable area was 97% when viewed from above the major surface of the soda-lime glass substrate.

Next, a mold release agent (GF-6110) was applied to the surface of the substrate with concave portions obtained as described above on which the concave portions were formed, and a non-polymerized (uncured) acrylic based resin (PMMA resin (methacryl resin)) was applied to the same surface side. At this time, substantially spherical-shaped spacers (each having a diameter of 2.0 mm) formed of hardened material of the acrylic based resin (PMMA resin (methacryl resin)) were arranged over the substantially entire surface of the substrate with concave portions for forming microlenses. Further, the spacers are arranged at the rate of 0.1 pieces/cm².

Next, the acrylic based resin was pressed (pushed) with the major surface of a flat plate formed of soda-lime glass. At this time, this process was carried out so that air was not intruded between the substrate with concave portions and the acrylic based resin. Further, such a flat plate onto the surface of which a mold release agent (GF-6110) was applied was utilized as the flat plate.

Then, by heating the substrate with concave portions, the acrylic based resin was cured to obtain a main substrate. The index of refraction of the obtained main substrate (that is cured acrylic based resin) was 1.51. The thickness of the obtained main substrate (except for portion where the microlenses were formed) was 2.0 mm. The length of each of the formed microlenses in the short axis direction thereof (pitch), the length of each of the formed microlenses in the long axis direction thereof, the radius of curvature and depth of each of the formed microlenses were 54 μm, 79.5 μm, 39 μm and 36.5 μm, respectively. Further, the share of the microlenses in a usable area in which the concave portions were formed was 97%.

Next, the flat plate was removed from the main substrate. Then, the main substrate was released from the substrate with concave portions.

A coloring liquid was then supplied to the main substrate by means of dip dyeing. This process was carried out so that the whole surface on which the microlenses were formed was brought into contact with the coloring liquid, but the surface that has been pressed with the flat plate was not in contact with the coloring liquid. Further, the temperature of the main substrate and the coloring liquid when supplying the first process liquid onto the main substrate was adjusted to be 90° C. Moreover, the pressure of the atmosphere was pressurized at the coloring liquid supplying process so as to be 120 kPa. A mixture containing disperse dye (Blue) (made by Futaba Sangyo): 2 part by weight, disperse dye (Red) (made by Futaba Sangyo): 0.1 part by weight, disperse dye (Yellow) (made by Futaba Sangyo): 0.05 part by weight, benzyl alcohol: 10 part by weight, a surfactant: 2 part by weight, and pure water: 1000 part by weight was used as the coloring liquid.

After the main substrate was brought into contact with the coloring liquid for 20 minutes under the conditions as described above, the main substrate was brought out from a bath in which the coloring liquid was stored, and the main substrate was then washed and dried.

By carrying out cleaning the main substrate with pure water and drying it with N₂ gas (removal of pure water), a microlens substrate on which the colored portion has been formed was obtained. The color density of the colored portion thus formed was 55%.

By assembling the microlens substrate manufactured as described above and a Fresnel lens manufactured by extrusion molding, the transmission screen as shown in FIG. 3 was obtained.

### Example 2

The shape and/or arrangement pattern of each of the concave portions in the substrate with concave portions were changed by appropriately changing irradiation conditions for the laser beams (that is, shape of each of the initial holes to be formed), and/or a soak time into an etchant. In this way, a main substrate was manufactured in the manner similar to that in Example 1 except that the shape and/or arrangement pattern of the microlenses to be formed in the microlens substrate were changed as shown in TABLE 1. In this case, by changing the size of each of spacers at this time, the thickness of the resin layer of the main substrate (portion except for the microlenses) was set to 0.005 mm.

Then, a positive type photopolymer to which a light shielding material (carbon black) was added (PC405G: made by JSR Corporation) was supplied onto the light emission surface of the main substrate (the surface opposite to the surface on which the microlenses had been formed) by means of a roll coater while the main substrate was in close contact with the substrate with concave portions (that is, at the state before the substrate with concave portions was removed from the main substrate). The content by percentage of the light shielding material in the photopolymer was 20% by weight.

Next, the main substrate was subjected to a pre-bake process of 90°×30 minutes.

Next, ultraviolet rays of 80 mJ/cm² were irradiated through the surface opposite to the surface of the substrate with concave portions on which the concave portions have been formed as parallel light. Thus, the irradiated ultraviolet rays were condensed by each of the microlenses, and the photopolymer in the vicinity of the focal point f of each of the microlenses (in the vicinity of the thickness direction of the black matrix) was exposed selectively.

The main substrate was then subjected to a developing process for 40 seconds using an aqueous solution containing 0.5% by weight KOH.

Then, cleaning with pure water and drying with N₂ gas (removal of pure water) were carried out. Further, the main substrate was subjected to a post-bake process of 200° C.×30 minutes. Thus, a black matrix having a plurality of openings respectively corresponding to the microlenses was formed. The thickness of the formed black matrix was 5.0. μm.

Next, a light diffusing portion was formed on the surface side of the main substrate on which the black matrix has been formed. The formation of the light diffusing portion was carried out by bonding a diffused plate having a structure in which silica particles were diffused in the acrylic resin as diffusion media to the main substrate by means of heat sealing.

Then, the microlens substrate provided with the black matrix and the diffused plate was released from the substrate with concave portions. Then, a transmission screen was manufactured as well as Example 1 described above using the obtained microlens substrate.

### Examples 3 to 11

A microlens substrate and a transmission screen were manufactured in the manner similar to those in Example 1 described above except that the shape of each of the concave portions and the arrangement pattern of the concave portions of the substrate with concave portions were changed by changing any of the configuration of the mask, the conditions of the irradiation with laser beams (that is, the shape of each of the initial holes to be formed and the depth of each of the initial concave portions) and the soaking time into the etchant, whereby the shape of each of the microlenses to be formed on the microlens substrate and the arrangement pattern of the microlenses were changed as shown in TABLE 1.

### Comparative Examples 1 to 6

A microlens substrate and a transmission screen were manufactured in the manner similar to those in Example 1 described above except that the shape of each of the concave portions and the arrangement pattern of the concave portions of the substrate with concave portions were changed by changing any of the configuration of the mask, the conditions of the irradiation with laser beams (that is, the shape of each of the initial holes to be formed and the depth of each of the initial concave portions) and the soaking time into the etchant, whereby the shape of each of the microlenses to be formed on the microlens substrate and the arrangement pattern of the microlenses were changed as shown in TABLE 1.

### Comparative Example 7

A microlens substrate and a transmission screen were manufactured in the manner similar to those in Comparative Example 1 described above except that the shape of each of the concave portions and the arrangement pattern of the concave portions of the substrate with concave portions were changed by changing any of the configuration of the mask, the conditions of the irradiation with laser beams (that is, the shape of each of the initial holes to be formed and the depth of each of the initial concave portions) and the soaking time into the etchant, whereby the shape of each of the microlenses to be formed on the microlens substrate and the arrangement pattern of the microlenses were changed as shown in TABLE 1, and that a colored portion was not formed on the main substrate.

A configuration of the mask, the shape of each of the initial holes formed by means of the irradiation with laser beams and the depth of each of the initial concave portions when manufacturing the substrate with concave portions, the shape of each of the concave portions and the arrangement pattern of the concave portions in the substrate with concave portions, the value of S/D (a ratio of the value S (μm) obtained by dividing the difference between the length of each of the concave portions in a long axis direction thereof and the diameter of each of the initial holes by two with respect to the depth D (μm) of each of the concave portions), the shape of each of the manufactured microlenses, the arrangement pattern of the manufactured microlenses, and presence or absence of the black matrix (BM) and the like in each of Examples 1 to 11 and Comparative Examples 1 to 7 were shown in TABLE 1 as a whole.

TABLE 1

| | Mask | | | | | Concave Portion | | | | | | | |
|---|---|---|---|---|---|---|---|---|---|---|---|---|---|
| | (Surface | Initial Hole | | | Initial | | | Length | Length | | | | |
| | Side/ | | Length | Length | Concave | | | (Short | (Long | | | | |
| | Substrate | | (Short | (Long | Portion | | Arrangement | Axis) | Axis) | Depth | | | Share |
| | Side) | Shape | Axis) (μm) | Axis) (μm) | Depth (Å) | Shape | Pattern | L1 (μm) | L2 (μm) | D (μm) | L1/D | L1/L2 | (%) |
| Ex. 1 | Cr/CrO | SC | 2.0 | 2.0 | 40 | SE | HC | 54 | 79.5 | 37.0 | 1.46 | 0.68 | 97 |
| Ex. 2 | Cr/CrO | SE | 2.0 | 2.1 | 50 | SE | HC | 54 | 82 | 38.0 | 1.42 | 0.66 | 100 |
| Ex. 3 | Cr/CrO | SE | 2.0 | 2.1 | 50 | SE | HC | 54 | 90 | 42.0 | 1.29 | 0.60 | 110 |
| Ex. 4 | Cr/CrO | SE | 3.9 | 4.0 | 70 | SE | HC | 54 | 60 | 27.8 | 1.94 | 0.90 | 100 |
| Ex. 5 | Cr/CrO | SE | 2.0 | 2.2 | 60 | SE | HC | 54 | 77 | 35.6 | 1.52 | 0.70 | 94 |
| Ex. 6 | Cr/CrO | SC | 2.0 | 2.0 | 40 | SE | HC | 40 | 72 | 33.5 | 1.19 | 0.56 | 97 |
| Ex. 7 | Au/Cr | SE | 2.0 | 2.1 | 60 | SE | HC | 54 | 78 | 34.2 | 1.58 | 0.69 | 100 |
| Ex. 8 | Au/Cr | SC | 2.0 | 2.0 | 40 | SE | HC | 54 | 78 | 31.0 | 1.74 | 0.69 | 98 |
| Ex. 9 | Cr/CrO | SC | 2.0 | 2.0 | 40 | SE | HC | 70 | 107 | 49.5 | 1.41 | 0.65 | 98 |
| Ex. 10 | Cr/CrO | SC | 2.0 | 2.0 | 40 | SE | HC | 54 | 72 | 33.3 | 1.62 | 0.75 | 88 |
| Ex. 11 | Cr/CrO | SC | 2.0 | 2.0 | 40 | SE | HC | 54 | 75.5 | 35.0 | 1.54 | 0.72 | 92 |
| Co-Ex. 1 | Cr/CrO | SC | 2.0 | 2.0 | 40 | S | SL | 60 | 60 | 27.8 | 2.16 | 1.00 | 100 |
| Co-Ex. 2 | Cr/CrO | SE | 1.9 | 2.0 | 40 | S | SL | 70 | 70 | 34.7 | 2.02 | 1.00 | 100 |
| Co-Ex. 3 | Cr/CrO | SE | 2.0 | 2.2 | 50 | S | SL | 80 | 80 | 37.0 | 2.16 | 1.00 | 100 |
| Co-Ex. 4 | Au/Cr | SC | 2.0 | 2.0 | 40 | S | SL | 80 | 80 | 35.1 | 2.28 | 1.00 | 85 |
| Co-Ex. 5 | Cr/CrO | SE | 2.0 | 2.1 | 50 | R | HC | 54 | 82 | 38.0 | 1.42 | 0.66 | 100 |
| Co-Ex. 6 | Cr/CrO | SE | 3.9 | 4.0 | 70 | R | HC | 54 | 90 | 41.7 | 1.29 | 0.60 | 100 |
| Co-Ex. 7 | Au/Cr | SE | 4.0 | 4.1 | 80 | R | HC | 54 | 90 | 39.5 | 1.37 | 0.60 | 85 |

| | | Microlens | | | | | | | | |
|---|---|---|---|---|---|---|---|---|---|---|
| | | | Arrangement | Length | Length | Height | | | | BM Presence |
| | S/D | Shape | Pattern | (Short Axis) L1 (μm) | (Long Axis) L2 (μm) | H (μm) | L1/H | L1/L2 | Share (%) | or Absence |
| Ex. 1 | 1.077 | SE | HC | 54 | 79.5 | 36.5 | 1.48 | 0.68 | 97 | A |
| Ex. 2 | 1.08 | SE | HC | 54 | 82 | 36.5 | 1.48 | 0.66 | 100 | P |
| Ex. 3 | 1.10 | SE | HC | 54 | 90 | 41.0 | 1.32 | 0.60 | 110 | A |
| Ex. 4 | 1.08 | SE | HC | 54 | 60 | 26.0 | 2.08 | 0.90 | 100 | A |
| Ex. 5 | 1.08 | SE | HC | 54 | 77 | 34.5 | 1.57 | 0.70 | 94 | A |
| Ex. 6 | 1.08 | SE | HC | 40 | 72 | 32.0 | 1.25 | 0.56 | 97 | A |
| Ex. 7 | 1.14 | SE | HC | 54 | 78 | 33.5 | 1.61 | 0.69 | 100 | A |
| Ex. 8 | 1.25 | SE | HC | 54 | 78 | 29.5 | 1.83 | 0.69 | 98 | A |
| Ex. 9 | 1.08 | SE | HC | 70 | 107 | 48.0 | 1.46 | 0.65 | 98 | P |
| Ex. 10 | 1.08 | SE | HC | 54 | 72 | 32.0 | 1.69 | 0.75 | 88 | A |
| Ex. 11 | 1.08 | SE | HC | 54 | 75.5 | 34.0 | 1.59 | 0.72 | 92 | A |
| Co-Ex. 1 | 1.08 | S | SL | 60 | 60 | 26.5 | 2.26 | 1.00 | 100 | A |
| Co-Ex. 2 | 1.08 | S | SL | 70 | 70 | 33.0 | 2.12 | 1.00 | 100 | A |
| Co-Ex. 3 | 1.08 | S | SL | 80 | 80 | 36.0 | 2.22 | 1.00 | 100 | A |
| Co-Ex. 4 | 1.14 | S | SL | 80 | 80 | 54.0 | 1.48 | 1.00 | 85 | A |
| Co-Ex. 5 | 1.08 | R | HC | 54 | 82 | 36.0 | 1.50 | 0.66 | 100 | A |
| Co-Ex. 6 | 1.08 | R | HC | 54 | 90 | 40.5 | 1.33 | 0.60 | 100 | A |
| Co-Ex. 7 | 1.14 | R | HC | 54 | 90 | 38.5 | 1.40 | 0.60 | 85 | A |

SHAPE SE: Substantially Elliptic, SC: Substantially Circle, S: Square, R: Rectangle
ARRANGEMENT PATTERN HC: Houndstooth Check, SL: Square Lattice

<Manufacture of Rear Projection>

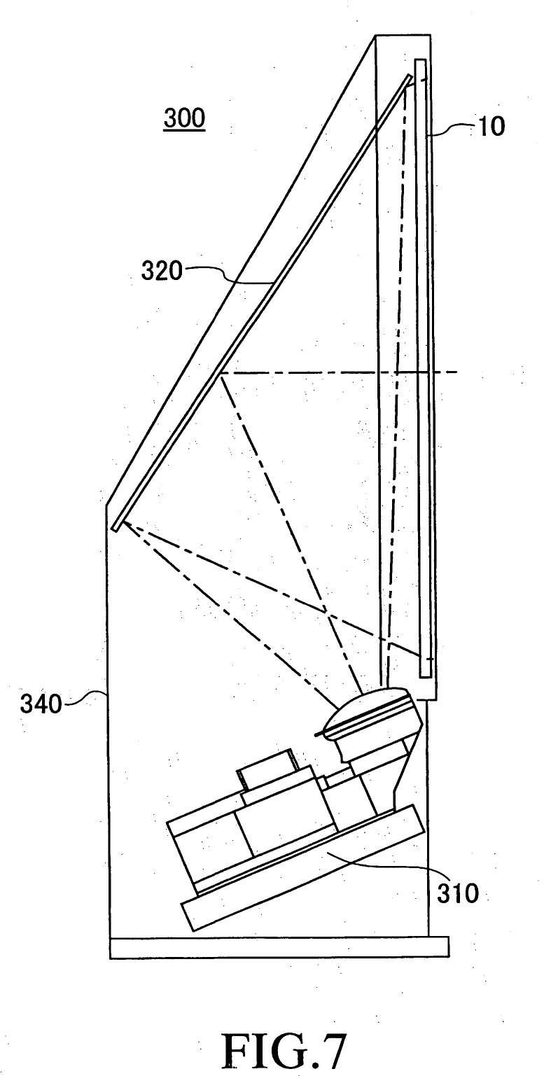

A rear projection as shown in FIG. 9 was manufactured (assembled) using the transmission screen manufactured in each of Examples 1 to 11 and Comparative Examples 1 to 7.

<Evaluation for Contrast>

The evaluation for contrast was carried out with respect to the rear projection of each of Examples 1 to 11 and Comparative Examples 1 to 7 described above.

A ratio LW/LB of front side luminance (white luminance) LW (cd/m²) of white indication when total white light having illuminance of 413 luces entered the transmission screen in the rear projection at a dark room to the increasing amount of front side luminance (black luminance increasing amount) LB (cd/m²) of black indication when a light source was fully turned off at a bright room was calculated as contrast (CNT). In this regard, the black luminance increasing amount is referred to as the increasing amount with respect to luminance of black indication at a dark room. Further, the measurement at the bright room was carried out under the conditions in which the illuminance of outside light was about 185 luces, while the measurement at the dark room was carried out under the conditions in which the illuminance of outside light was about 0.5 luces.

The contrast indicated by LW/LB in each of Examples 1 to 11 and Comparative Examples 1 to 7 was evaluated on the basis of the following four-step standard.

A: The contrast indicated by LW/LB is 500 or more.

B: The contrast indicated by LW/LB is in the range of 400 to 500.

C: The contrast indicated by LW/LB is in the range of 300 to 400.

D: The contrast indicated by LW/LB is 300 or less.

<Evaluation of Diffracted Light, Moire and Color Heterogeneity>

A sample image was displayed on the transmission screen of the rear projection in each of Examples 1 to 11 and Comparative Examples 1 to 7 described above. The generation status of diffracted light, moire and color heterogeneity in the displayed sample image was evaluated on the basis of the following four-step standard.

A: No diffracted light, moire and color heterogeneity was recognized.

B: Little diffracted light, moire and color heterogeneity was recognized.

C: At least one of diffracted light, moire and color heterogeneity was slightly recognized.

D: At least one of diffracted light, moire and color heterogeneity was remarkably recognized.

<Measurement of Angle of View>

The measurement of angles of view in both horizontal and vertical directions was carried out while a sample image was displayed on the transmission screen in the rear projection of each of Examples 1 to 11 and Comparative Examples 1 to 3. The measurement of the angles of view was carried out under the conditions in which the measurement was carried out at intervals of five degree with a gonio photometer. These results of the measurement of angles of view were shown in TABLE 2 as a whole.

TABLE 2

| | | | Angle of View (°) | | Angle of View (°) | |
|---|---|---|---|---|---|---|
| | | Diffracted Light, | α (½ attenuation) | | α ( 1/10 attenuation) | |
| | | Moire, Color | Vertical | Horizontal | Vertical | Horizontal |
| | Contrast | Heterogeneity | Direction | Direction | Direction | Direction |
| Ex. 1 | A | A | 20 | 23 | 33 | 60 |
| Ex. 2 | A | A | 21 | 25 | 30 | 59 |
| Ex. 3 | A | B | 20 | 23 | 27 | 60 |
| Ex. 4 | A | A | 20 | 23 | 30 | 60 |
| Ex. 5 | A | B | 18 | 21 | 28 | 61 |
| Ex. 6 | A | A | 20 | 23 | 29 | 57 |
| Ex. 7 | A | A | 20 | 23 | 28 | 55 |
| Ex. 8 | A | A | 20 | 25 | 27 | 54 |
| Ex. 9 | A | C | 21 | 23 | 30 | 59 |
| Ex. 10 | A | A | 18 | 19 | 26 | 58 |
| Ex. 11 | A | A | 18 | 19 | 27 | 57 |
| Co. Ex. 1 | C | C | 16 | 18 | 25 | 46 |
| Co. Ex. 2 | C | C | 16 | 18 | 26 | 46 |
| Co. Ex. 3 | C | C | 15 | 19 | 24 | 47 |
| Co. Ex. 4 | C | C | 15 | 17 | 23 | 45 |
| Co. Ex. 5 | C | B | 16 | 18 | 24 | 44 |
| Co. Ex. 6 | C | B | 16 | 18 | 25 | 44 |
| Co. Ex. 7 | C | B | 16 | 18 | 24 | 44 |

As seen clearly from TABLE 2, the rear projection in each of Examples 1 to 11 according to the invention had excellent contrast and excellent angle of view characteristics. Further, an excellent image having no diffracted light, moire and color heterogeneity could be displayed on each of the rear projections in each of Examples 1 to 11 according to the invention. In other words, an excellent image could be displayed on each of the rear projections in each of Examples 1 to 11 according to the invention stably. On the other hand, sufficient results could not be obtained from the rear projection in each of Comparative Examples 1 to 7 described above.

What is claimed is:

1. A method of manufacturing a substrate provided with a plurality of concave portions, the substrate being used for manufacturing a microlens substrate provided with a plurality of microlenses as convex lenses which are to be formed using the plurality of concave portions, the method comprising the steps of:
preparing a base substrate, the base substrate having two major surfaces;
forming at least one layer on the one of the two major surfaces of the base substrate;
forming a plurality of openings in the at least one layer to form a mask, the diameter of each of the plurality of openings being in the range of 0.8 to 20 μm;
forming the plurality of concave portions in the base substrate by subjecting the base substrate with the mask on which the plurality of openings have been formed to an etching process so that each of the formed concave portions has a substantially elliptic shape; and
removing the mask from the base substrate,
wherein the plurality of formed concave portions are arranged on the base substrate in a houndstooth check manner,
wherein, in the case where the depth of each of the formed concave portions in a direction perpendicular to the major surface of the base substrate is defined as D (μm) and the value obtained by dividing the difference between the length of each of the formed concave portions in a long axis direction thereof and the diameter of each of the formed openings by two is defined as S (μm), then D and S satisfy the relation: 0.90≦S/D≦1.40, and
wherein a ratio of an area occupied by all the plurality of formed concave portions in a usable area where the plurality of concave portions are formed with respect to the entire usable area is 90% or more when viewed from above the one major surface of the base substrate.

2. The method as claimed in claim 1, wherein in the openings forming step the plurality of openings are formed so that a first column of concave portions is shifted by a half pitch of each of the plurality of concave portions in a short axis direction thereof with respect to a second column of concave portions which is adjacent to the first column of concave portions when viewed from above the one major surface of the base substrate.

3. The method as claimed in claim 1, wherein the at least one layer forming step includes the steps of:
forming a first layer constituted from chromium as a main material on the one major surface of the base substrate; and
forming a second layer constituted from chromium oxide as a main material on the first layer.

4. The method as claimed in claim 1, wherein the openings forming step includes the step of irradiating the base substrate on which the at least one layer has been formed with laser beams.

5. The method as claimed in claim 1, wherein in the concave portions forming step the etching process is carried out using a liquid containing ammonium hydrogen difluoride as an etchant.

6. The method as claimed in claim 4, wherein in the base substrate preparing step the base substrate constituted from a material having transparency is used.

7. The method as claimed in claim 1, wherein, in the case where the length of each of the formed concave portions having a substantially elliptic shape in the short axis direction thereof is defined as L₁ (μm) and the length of each of the formed concave portions in the long axis direction thereof is defined as L₂ (μm), then L₁ and L₂ satisfy the relation: 0.10≦L₁/L₂≦0.99.

8. A substrate provided with a plurality of concave portions manufactured using the method defined by claim 1.

9. A microlens substrate manufactured using the substrate with the plurality of concave portions defined by claim 8, wherein the microlens substrate has two major surfaces, and a plurality of microlenses are formed on the one major surface of the microlens substrate.

10. The microlens substrate as claimed in claim 9, wherein the plurality of microlenses are formed on the one major surface of the microlens substrate so that a first column of microlenses is shifted by a half-pitch of each of the plurality of microlenses in a short axis direction thereof with respect to a second column of microlenses which is adjacent to the first column of microlenses when viewed from above the one major surface of the microlens substrate.

11. The microlens substrate as claimed in claim 9, wherein, in the case where the length of each of the plurality of microlenses having a substantially elliptic shape in the short axis direction thereof is defined as L₁ (μm) and the length of each of the plurality of microlenses in the long axis direction thereof is defined as L₂ (μm), then L₁ and L₂ satisfy the relation: 0.10≦L₁/L₂≦0.99.

12. The microlens substrate as claimed in claim 9, wherein the microlens substrate is constituted from a material having transparency.

13. A transmission screen comprising:
a Fresnel lens formed with a plurality of concentric prisms on one major surface thereof, the one major surface of the Fresnel lens constituting an emission surface thereof; and
the microlens substrate defined by claim 9, the microlens substrate being arranged on the side of the emission surface of the Fresnel lens so that the one major surface thereof faces the Fresnel lens.

14. A rear projection comprising the transmission screen defined by claim 13.
